(19) United States
(12) Patent Application Publication
(10) Pub. No.: US 2024/0329624 A1
(43) Pub. Date: Oct. 3, 2024

(54) SCHEDULE CREATION PROGRAM GENERATING METHOD, SCHEDULE CREATION PROGRAM GENERATING APPARATUS, SCHEDULE CREATING APPARATUS, RECORDING MEDIUM, SUBSTRATE PROCESSING APPARATUS, AND SUBSTRATE PROCESSING SYSTEM

(71) Applicant: SCREEN Holdings Co., Ltd., Kyoto (JP)

(72) Inventors: Jun KAWAI, Kyoto (JP); Takashi KASAHARA, Kyoto (JP)

(21) Appl. No.: 18/614,475

(22) Filed: Mar. 22, 2024

(30) Foreign Application Priority Data
Mar. 27, 2023 (JP) 2023-049347

(51) Int. Cl. G05B 19/418; G06Q 10/0639

(52) U.S. Cl. CPC G05B 19/41865; G06Q 10/0639; G05B 2219/45031

(57) ABSTRACT

A schedule creation program generating method generates, through reinforcement learning, a schedule creation program for creating a time schedule for a plurality of components included in a substrate processing apparatus. The method includes: increasing a value of a reward by repeating experiencing through the reinforcement learning, the experiencing including arranging and reward determining; and changing a reward function that defines a relationship between an amount of time taken according to the time schedule and a value of a corresponding reward. The arranging includes sequentially arranging a plurality of planning factors in a timetable, the plurality of planning factors being given in advance to each of the plurality of substrates. The reward determining includes determining the value of the corresponding reward based on the reward function. The changing includes changing the reward function whose gradient in a partial section is larger than a gradient in the partial section of the reward function before the changing.

### INCORPORATION BY REFERENCE

The present application claims priority under 35 U.S.C. § 119 to Japanese Patent Application No. 2023-049347, filed on Mar. 27, 2023. The contents of this application are incorporated herein by reference in their entirety.

### BACKGROUND

The subject matter of the present application relates to a schedule creation program generating method, a schedule creation program generating apparatus, a schedule creating apparatus, a recording medium, a substrate processing apparatus, and a substrate processing system.

A schedule creating method for substrate processing apparatus is known (e.g., JP 2009-48320 A). The schedule creating method for substrate processing apparatus is a method of creating a time schedule for each component of the substrate processing apparatus. This approach by the schedule creating method for substrate processing apparatus enables creating a time schedule according to which a substrate processing apparatus is to efficiently process substrates one by one (a single substrate at a time) or in lots (e.g., per 25 substrates). For example, a schedule creating method disclosed in JP 2009-48320 A is applied to a batch type of substrate processing apparatus. Specifically, the schedule creating method disclosed in JP 2009-48320 A creates, in lots, a time schedule for each component of a substrate processing apparatus.

A schedule creating method for substrate processing apparatus is implemented by a controller executing a computer program. Here, the controller includes a central processing unit (CPU) and a counter timer. The developers of the schedule creating method therefore develop a processing flow to be executed by a processor. Specifically, the developers determine rules (constraints) in consideration of an apparatus configuration of the substrate processing apparatus and develop the processing flow to be executed by the processor so that a time schedule that reflects the rules determined can be created.

In this way, the rules (constraints) are determined in consideration of the apparatus configuration of the substrate processing apparatus and the processing flow to be executed by the processor is developed so that the time schedule that reflects the rules determined can be created. However, in this case, the apparatus configuration differs for each of unit types and therefore the developers need to develop the entire flow for each unit type.

### SUMMARY

A schedule creation program generating method according to an aspect of the present disclosure generates, through reinforcement learning, a schedule creation program for creating a time schedule for a plurality of components included in a substrate processing apparatus. While a substrate of the plurality of substrates is being processed, the substrate occupies the plurality of components. The schedule creation program generating method includes: increasing a value of a reward by repeating experiencing through the reinforcement learning, the experiencing including arranging and reward determining; and changing a reward function that defines a relationship between an amount of time taken according to the time schedule and a value of a corresponding reward. The arranging includes sequentially changing a state of a timetable by sequentially arranging a plurality of planning factors in the timetable, the timetable defining the time schedule, the plurality of planning factors being given in advance to each of the plurality of substrates. The reward determining includes determining the value of the corresponding reward based on the reward function and a final state of the timetable in which all the plurality of planning factors is arranged. The time schedule corresponds to the final state of the timetable. The changing includes changing the reward function whose gradient in a partial section is larger than a gradient in the partial section of the reward function before the changing, the partial section being part of a time range from an amount of time taken according to a time schedule corresponding to a reward with a maximum value to an amount of time taken according to a time schedule corresponding to a reward with a minimum value.

In an embodiment, the changing includes changing to a reward function whose gradient in the partial section is larger than a gradient in the partial section of a linear function that is set in all the time range.

In an embodiment, the changing included in the schedule creation program generating method is repeated more than once. The changing includes changing to a reward function whose gradient in the partial section is larger than a gradient in the partial section of an active reward function each time the changing is repeated.

In an embodiment, the changing further includes shifting the partial section.

In an embodiment, the plurality of components includes a plurality of substrate processing sections and a conveyance section. The plurality of substrate processing sections processes the plurality of substrates. The conveyance section conveys the plurality of substrates. The plurality of planning factors includes a first planning factor and a second planning factor. The first planning factor is a plan to load a substrate of the plurality of substrates into a substrate processing section of the plurality of substrate processing sections through the conveyance section to process the substrate through the substrate processing section. The second planning factor is a plan to unload the substrate processed by the substrate processing section from the substrate processing section through the conveyance section.

In an embodiment, an amount of time taken according to the first planning factor is larger than an amount of time taken according to the second planning factor.

In an embodiment, the plurality of planning factors includes respective planning factors corresponding to the plurality of substrate processing sections. The arranging includes selecting a planning factor of the plurality of planning factors respectively corresponding to the plurality of substrate processing sections.

A schedule creation program generating apparatus according to an aspect of the present disclosure generates, through reinforcement learning, a schedule creation program for creating a time schedule for a plurality of components included in a substrate processing apparatus. The schedule creation program generating apparatus includes storage and a processor. The storage stores a creation program that defines the schedule creation program generating method described above. The processor executes the creation program to generate the schedule creation program.

A schedule creating apparatus according to an aspect of the present disclosure creates a time schedule for a plurality of components included in a substrate processing apparatus. The schedule creating apparatus includes storage and a processor. The storage stores a schedule creation program that is created based on the schedule creation program generating method described above. The processor executes the schedule creation program to create the time schedule.

A recording medium according to an aspect of the present disclosure is a non-transitory computer readable medium. The recording medium stores a creation program that defines the schedule creation program generating method described above.

A recording medium according to an aspect of the present disclosure is a non-transitory computer readable medium. The recording medium stores a schedule creation program created through the schedule creation program generating method described above.

A substrate processing apparatus according to an aspect of the present disclosure process a substrate. The substrate processing apparatus includes a plurality of components, storage, and a processor. While a substrate of a plurality of substrates is being processed, the substrate occupies the plurality of components. The storage stores a creation program that defines the schedule creation program generating method described above. The processor executes the creation program to generate the schedule creation program for creating the time schedule for the plurality of components. The processor executes the schedule creation program to create the time schedule.

A substrate processing apparatus according to an aspect of the present disclosure processes a substrate. The substrate processing apparatus includes a plurality of components, storage, and a processor. While a substrate of a plurality of substrates is being processed, the substrate occupies the plurality of components. The storage stores a schedule creation program that is generated through the schedule creation program generating method described above. The processor executes the schedule creation program to create the time schedule for the plurality of components.

A substrate processing system according to an aspect of the present disclosure includes a substrate processing apparatus that processes a substrate and the schedule creation program generating apparatus described above. The schedule creation program generating apparatus further includes a transmitter that transmits the schedule creation program to the substrate processing apparatus. The substrate processing apparatus includes a plurality of components, a receiver, and a processor. While a substrate of a plurality of substrates is being processed, the substrate occupies the plurality of components. The receiver receives the schedule creation program transmitted from the transmitter of the schedule creation program generating apparatus. The processor executes the schedule creation program to create the time schedule for the plurality of components.

A substrate processing system according to an aspect of the present disclosure includes a substrate processing apparatus that processes a substrate and the schedule creating apparatus described above. The schedule creating apparatus further includes a transmitter that transmits the time schedule to the substrate processing apparatus. The substrate processing apparatus includes a plurality of components and a receiver. While a substrate of a plurality of substrates is being processed, the substrate occupies the plurality of components. The receiver receives the time schedule transmitted from the transmitter of the schedule creating apparatus.

### BRIEF DESCRIPTION OF THE DRAWINGS

FIGS. 1A and 1B illustrate a schedule creation program generating system including a schedule creation program generating apparatus according to a first embodiment.

FIG. 2 illustrates an example of a substrate processing apparatus to which a schedule creation program in the first embodiment is applied.

FIG. 3 illustrates respective examples of processing procedure, processing time, and planning factor.

FIG. 4 illustrates details of a second planning factor in FIG. 3.

FIG. 5 illustrates an example of a timetable corresponding to the substrate processing apparatus in FIG. 2.

FIG. 6 illustrates an example of a process flow of creating a time schedule.

FIG. 7 is a block diagram of a reinforcement learning system.

FIG. 8 is a flow chart depicting a schedule creation program generating method according to the first embodiment.

FIG. 9 is a flow chart depicting a time schedule creating process.

FIG. 10 is a flow chart depicting a process of randomly selecting one of actions and arranging a planning factor in a timetable.

FIG. 11 is a flow chart depicting a process of predicting an action that will maximize a reward and arranging a planning factor in a timetable.

FIG. 12A is a flow chart depicting a first change process included in a change process.

FIG. 12B is a flow chart depicting a second change process included in the change process.

FIG. 13 illustrates an example of a first change process.

FIG. 14 illustrates another example of the first change process.

FIG. 15 illustrates an example of a second change process.

FIG. 16 illustrates another example of the change process.

FIG. 17 illustrates a substrate processing system including the substrate processing apparatus according to the first embodiment.

FIG. 18 illustrates a substrate processing system including a substrate processing apparatus according to a second embodiment.

FIG. 19 illustrates a substrate processing system according to a third embodiment.

FIG. 20 illustrates a substrate processing system according to a fourth embodiment.

### DETAILED DESCRIPTION

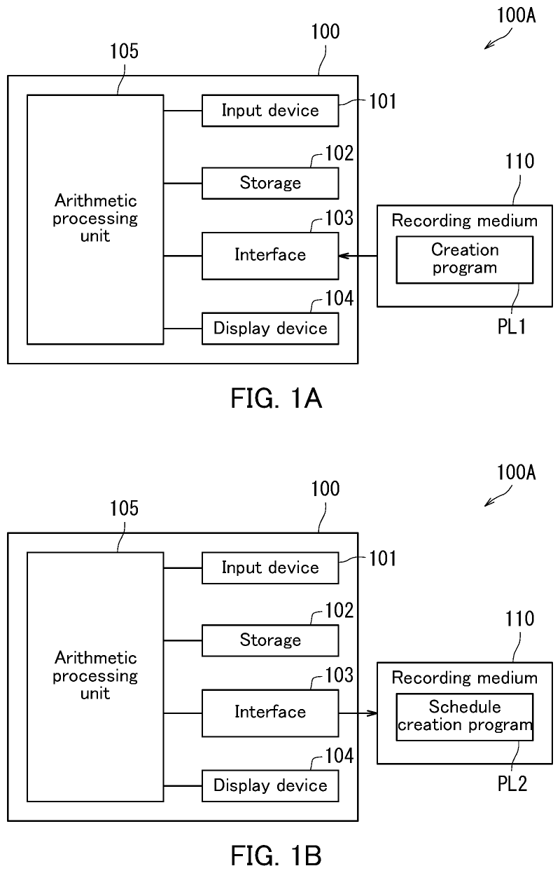

The following describes embodiments according to a schedule creation program generating method, a schedule creation program generating apparatus, a schedule creating apparatus, a recording medium, a substrate processing apparatus, and a substrate processing system of the present disclosure with reference to the drawings (FIGS. 1A, 1B, and 2 to 20). The subject matter of the present application is not limited to the following embodiments and can be practiced in various ways within the scope without departing from the essence of the present disclosure. Note that duplicate descriptions may be omitted as appropriate. Elements that are the same or equivalent are labelled with the same reference signs in the drawings and description thereof is not repeated.

Examples applicable to “substrate” in the embodiments include various substrates such as a semiconductor wafer, a photomask glass substrate, a liquid crystal display glass substrate, a plasma display glass substrate, a field emission display (FED) substrate, an optical disk substrate, a magnetic disk substrate, and magneto-optical disk substrate. The following mainly describes, as examples used for processing a semiconductor wafer shaped like a disk, the embodiments according to the schedule creation program generating method, the schedule creation program generating apparatus, the schedule creating apparatus, the recording medium, the substrate processing apparatus, and the substrate processing system. However, the subject matter of the present disclosure is equally applicable to the processing of the above various substrates. Furthermore, various shapes of substrates can be applied.

### First Embodiment

A first embodiment will be described below with reference to FIGS. 1A, 1B, and 2 to 17. FIGS. 1A and 1B illustrate a schedule creation program generating system 100A including a schedule creation program generating apparatus 100 according to the present embodiment. Specifically, FIG. 1A illustrates the schedule creation program generating system 100A before a schedule creation program PL2 is created. FIG. 1B illustrates the schedule creation program generating system 100A after the schedule creation program PL2 is created.

As depicted in FIG. 1A, the schedule creation program generating system 100A includes the schedule creation program generating apparatus 100 and a recording medium 110.

The recording medium 110 is a non-transitory computer readable medium and stores a program (computer program) to be executed by computers. The recording medium 110 stores a creation program PL1. The creation program PL1 is a computer program executable by computers.

Examples of the recording medium 110 include semiconductor memory such as an SD memory card and universal serial bus (USB) memory, and a magnetic disk such as a hard disk drive. Examples thereof may further include optical discs such as a compact disk (CD), a digital versatile disk (DVD), and a Blu-ray Disc™. Examples thereof may also include main memory and auxiliary memory installed in other computer systems.

The schedule creation program generating apparatus 100 generates a schedule creation program PL2 for creating a time schedule for a plurality of components included in a substrate processing apparatus WP based on the creation program PL1. Specifically, the creation program PL1 includes a reinforcement learning program. The schedule creation program generating apparatus 100 generates the schedule creation program PL2 through reinforcement learning. Examples of the schedule creation program generating apparatus 100 include a general-purpose computer system and a dedicated computer system.

As depicted in FIG. 1A, the schedule creation program generating apparatus 100 includes an input device 101, storage 102, an interface 103, a display device 104, and an arithmetic processing unit 105.

The interface 103 exchanges information, data, or signals with the recording medium 110. The interface 103 reads the creation program PL1 from the recording medium 110 and enters the creation program PL1 into the arithmetic processing unit 105. The creation program PL1 is consequently installed in the schedule creation program generating apparatus 100. As depicted in FIG. 1B, the interface 103 causes the recording medium 110 to carry the schedule creation program PL2.

For example, the interface 103 may be electrically connected with the recording medium 110 to exchange information, data, or signals with the recording medium 110. For example, the interface 103 may include a slot and a USB terminal. For example, a card-shaped information carrier such as an SD memory card may be inserted into the slot. For example, a USB memory may be inserted into the USB terminal, or the other end of a USB cable having one end electrically connected to a hard disk drive may be inserted into the USB terminal. Alternatively, the interface 103 may include an optical disc drive. The optical disc drive reads information (data) from a compact disc (CD), a DVD, and/or a Blu-ray Disc™. The optical disc drive also writes information (data) to CD, DVD, and/or Blu-ray disc.

The interface 103 may receive the creation program PL1 from another computer system. For example, the interface 103 may be connected to another computer system via a cable with mutual communication allowed through the cable. The interface 103 may also be connected to other computer systems via a line network such as the Internet with mutual communication allowed through the line network.

The input device 101 includes a user interface device that allows operators to operate. The input device 101 enters a signal in response to operators' operation into the arithmetic processing unit 105. Examples of the input device 101 include a keyboard and a mouse. Examples thereof may also include a touch sensor superimposed on a display surface of the display device 104. Thus, a graphical user interface may be configured by superimposing the touch sensor on the display surface of the display device 104.

The input device 101 allows operators to operate, thereby issuing an instruction on installing the creation program PL1, for example. The input device 101 allows operators to operate, thereby issuing an instruction on starting reinforcement learning. The input device 101 allows operators to operate, thereby setting ending conditions imposed on reinforcement learning. Examples of the ending conditions imposed on reinforcement learning may include setting a threshold for the number of times (trial numbers) to repeat time schedule creation. In this case, the number of times (trial numbers) to repeat time schedule creation reaches the threshold and then the reinforcement learning ends. Hereinafter, the threshold set as ending conditions imposed on reinforcement learning may be referred to as a “first threshold”.

In the present embodiment, one time schedule is to be created in one step of the reinforcement learning. In other words, one time schedule is created and then one episode of the reinforcement learning ends. The number of times (trial numbers) to repeat time schedule creation therefore corresponds to the number of times to repeat the step of the reinforcement learning.

The display device 104 presents various screens under the control of the arithmetic processing unit 105. Specifically, the display device 104 may present a learning curve. The learning curve depicts a relationship between step iteration numbers of reinforcement learning (the number of step iterations in the reinforcement learning) and a corresponding reward. Examples of the display device 104 include a liquid crystal display device and an organic electroluminescent (EL) display device.

The storage 102 includes main memory. Examples of the main memory include semiconductor memory. The storage 102 may further include auxiliary storage. Examples of the auxiliary storage include semiconductor memory and a hard disk drive. The storage 102 may include removable media. The storage 102 stores various computer programs and various pieces of data. Specifically, the storage 102 stores the creation program PL1. The storage 102 also stores the ending conditions imposed on the reinforcement learning. The storage 102 stores, as the ending conditions imposed on the reinforcement learning, the first threshold that is set through the input device 101 operated by operators, for example.

As described above, the creation program PL1 includes the reinforcement learning program. Examples of a reinforcement learning algorithm include, but not particularly limited to, respective algorithms according to Q-learning, SARSA, policy gradient methods, actor-critic methods, and Monte Carlo methods.

Artificial neural networks for reinforcement learning may include artificial neural networks that perform deep learning. Specific examples of an artificial neural network include a deep neural network (DNN), a deep Q-network (DQN), a recurrent neural network (RNN), a convolutional neural network (CNN), and a quantum neural network (QNN). For example, the deep neural network includes an input layer, multiple hidden layers, and an output layer.

The arithmetic processing unit 105 includes a processor. Examples of the arithmetic processing unit 105 include a central processing unit (CPU), a microprocessor unit (MPU), a graphics processing unit (GPU), a neural network processing unit (NPU), and a quantum computer. Examples of the arithmetic processing unit 105 may include a general-purpose arithmetic device and a dedicated arithmetic device. Examples of the arithmetic processing unit 105 may also include a field-programmable gate array (FPGA) and an application-specific integrated circuit (ASIC).

The arithmetic processing unit 105 executes the creation program PL1 stored in the storage 102 to generate the schedule creation program PL2. The arithmetic processing unit 105 then stores the schedule creation program PL2 in the recording medium 110.

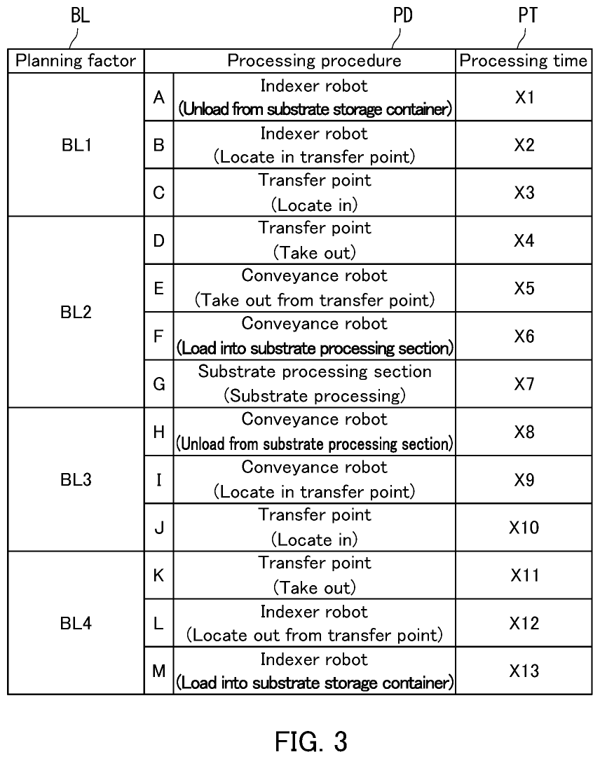

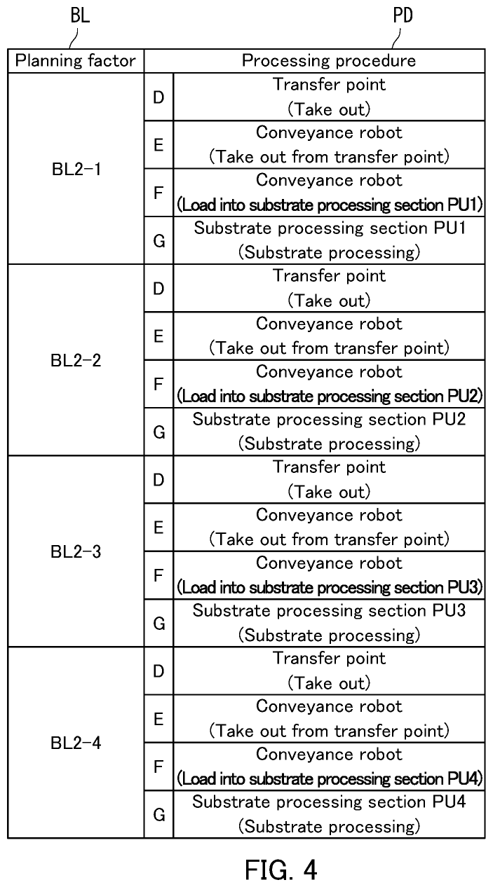

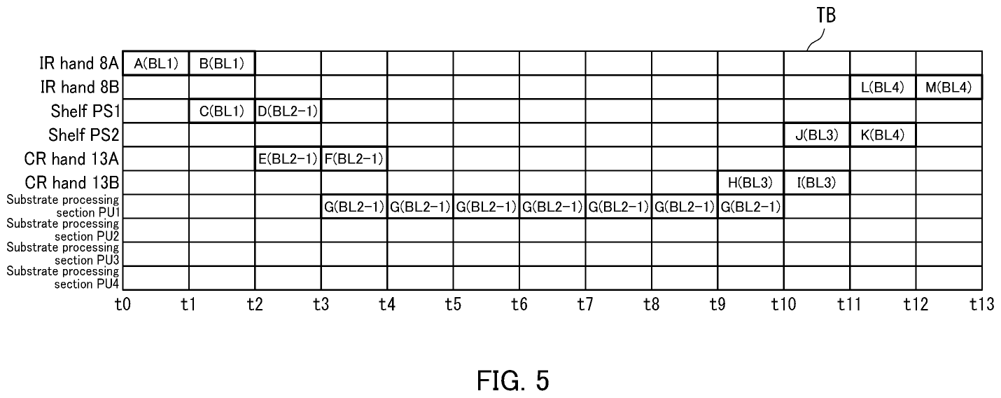

Specifically, in each step of reinforcement learning, the arithmetic processing unit 105 arranges a plurality of planning factors BL in a timetable TB. The plurality of planning factors BL will be described with reference to FIGS. 3 and 4. The timetable TB will be described with reference to FIG. 5. As a result, the arithmetic processing unit 105 creates a time schedule for a plurality of components included in the substrate processing apparatus WP. Specifically, the arithmetic processing unit 105 repeats a trial step of creating a time schedule through the reinforcement learning.

For example, the arithmetic processing unit 105 repeats a trial step of creating a time schedule for processing 25 substrates W on the condition that four planning factors BL are arranged in a timetable TB for each substrate W. In this case, 100 planning factors BL are arranged in the timetable TB in each step of the reinforcement learning. Information on the timetable TB is stored in the storage 102. The information on the timetable TB may be included in the creation program PL1 and may be entered through the input device 101 operated by operators.

Specifically, the creation program PL1 includes a reward function that is defined to provide a higher reward as an amount of time taken according to the time schedule is smaller. The arithmetic processing unit 105 refers to the reward function and acquires a reward each time a time schedule is created. The arithmetic processing unit 105 adjusts the parameters (weighting coefficients) of the artificial neural networks such that a reward has a maximum value in a process of repeating the step (trial) of the reinforcement learning. The arithmetic processing unit 105 therefore adjusts the parameters of the artificial neural networks so that an amount of time taken according to the time schedule is smaller. For example, the parameters of the artificial neural networks are adjusted until the trial numbers reach the first threshold. As a result, the schedule creation program PL2 (trained model) is generated (built). The time schedule is created through the schedule creation program PL2 generated in this way. This approach enables creation of a time schedule which a process of processing a predetermined number of substrates W will be completed in a shorter period of time according to.

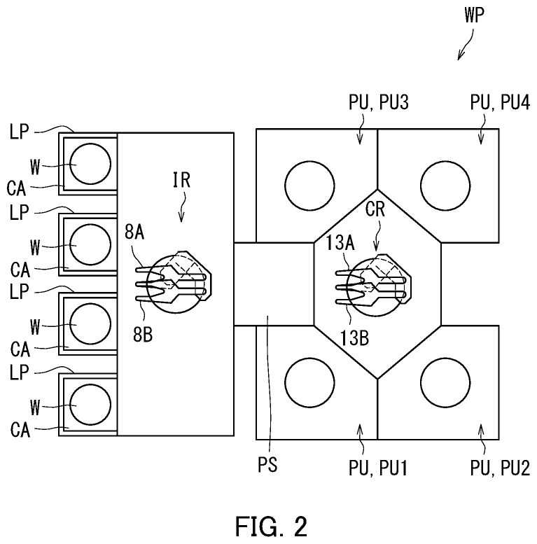

An example of a substrate processing apparatus WP to which a schedule creation program PL2 is applied will then be described with reference to FIG. 2. FIG. 2 illustrates an example of the substrate processing apparatus WP to which the schedule creation program PL2 in the present embodiment is to be applied.

The substrate processing apparatus WP in FIG. 2 is a single-wafer type apparatus and processes substrates W one by one. The substrate processing apparatus WP in FIG. 2 includes 4 load ports LP, an indexer robot IR, a transfer point PS, a conveyance robot CR, and four substrate processing section PU (a first substrate processing section PU1, a second substrate processing section PU2, a third substrate processing section PU3, and a fourth substrate processing section PU4).

The load ports LP are provided with their respective substrate storage containers CA. Each of the substrate storage containers CA stores a plurality of substrates W in a stacked state. Specifically, the plurality of substrates W in the substrate storage container CA is vertically stacked at intervals in a horizontal position. Here, the horizontal position is a state in which the thickness direction of each substrate W corresponds to the vertical direction. Examples of the substrate storage container CA include a front opening unified pod (FOUP), a standard mechanical interface (SMIF) pod, and an open cassette (OC).

The indexer robot IR conveys a substrate W to be processed from a substrate storage container CA to the transfer point PS. The indexer robot IR also conveys the substrate W processed from the transfer point PS to the substrate storage container CA. Here, the substrate W to be processed is the substrate W before being processed by a corresponding substrate processing section PU. The substrate W processed is the substrate W processed by the corresponding substrate processing section PU. The indexer robot IR is an example of a “conveyance section”.

The indexer robot IR includes two hands (hands 8A and 8B). Each of the hands 8A and 8B holds one substrate W. Specifically, the hand 8A holds a substrate W to be processed. The hand 8B holds the substrate W processed. Note that the hands 8A and 8B may be arranged to overlap vertically. In FIG. 2, for clarity, the hands 8A and 8B are shifted in a direction (horizontal direction) parallel to the paper.

The transfer point PS includes a plurality of shelves that supports substrates W. Specifically, the transfer point PS includes at least one shelf that supports a substrate W to be processed and at least one shelf that supports a substrate W processed. In the present embodiment, the transfer point PS includes one shelf that supports a substrate W to be processed and one shelf that supports a substrate W processed. Hereinafter, the shelf that supports a substrate W to be processed may be referred to as a “shelf PS1”. The shelf that supports a substrate W processed may be referred to as a “shelf PS2”.

The conveyance robot CR conveys a substrate W to be processed from the transfer point PS to any one of the substrate processing sections PU. The conveyance robot CR also conveys a substrate W processed to the transfer point PS from a substrate processing section PU which has processed the substrate W. The conveyance robot CR is an example of the “conveyance section”. Specifically, the conveyance robot CR includes two hands (hands 13A and 13B). Each of the hands 13A and 13B holds one substrate W. Specifically, the hand 13A holds a substrate W to be processed. The hand 13B holds a substrate W processed. Note that the hands 13A and 13B may be arranged to overlap vertically. In FIG. 2, for clarity, the hands 13A and 13B are shifted in a direction (horizontal direction) parallel to the paper.

The substrate processing sections PU each process substrates W one by one. Each substrate W is processed by any one of the four substrate processing sections PU (first to fourth substrate processing sections PU1 to PU4). The content of a process performed by the substrate processing sections PU is not particularly limited. Examples of processing performed on substrates W by the substrate processing sections PU include processing using a processing agent, processing using electromagnetic waves such as ultraviolet rays, and physical cleaning processing. The processing agent includes either or both of a processing liquid or/and a processing gas. Examples of the physical cleaning processing include brush cleaning and spray nozzle cleaning. Examples of substrate processing performed on substrates W by the substrate processing sections PU include chemical cleaning processing, brush cleaning processing, wet etching processing, dry etching processing, photoresist film coating processing, development processing, annealing processing, and drawing processing.

Processing procedure PD, processing time PT, and planning factor BL will be described with reference to FIGS. 3 and 4. FIG. 3 depicts an example of processing procedure PD, processing time PT, and planning factor BL. Specifically, FIG. 3 depicts processing procedure PD, processing time PT, and planning factor BL depicted in FIG. 3 corresponds to a substrate processing apparatus WP (see FIG. 2). Information on processing procedure PD, information on processing time PT, and information on planning factor BL are associated with each other and stored in storage 102 (see FIGS. 1A and 1B). These pieces of information may be entirely or partially included in a creation program PL1 or may be entered through the input device 101 operated by operators.

The processing procedure PD is the procedure for processing to be performed through the substrate processing apparatus WP. Specifically, the processing procedure PD is the procedure for processing to be performed by a plurality of components included in the substrate processing apparatus WP.

As depicted in FIG. 3, the processing procedure PD corresponding to the substrate processing apparatus WP as depicted in FIG. 2 includes processing patterns A to M. The processing patterns A to M are performed in this order with respect to one substrate W. The processing procedure PD indicates the flow of a process (process flow) performed on one substrate W. The processing patterns A to M are arranged in this order in a timetable TB to be described with reference to FIG. 5 along the time axis of the timetable TB.

The processing pattern A is a process step of unloading a substrate W to be processed from a substrate storage container CA through an indexer robot IR. The processing pattern B is a process step of, through the indexer robot IR, conveying the substrate W to be processed to a transfer point PS and then locating the substrate W to be processed in the transfer point PS. During the performance of the processing pattern A, one substrate W occupies a hand 8A of the indexer robot IR. During the performance of the processing pattern B, one substrate W occupies the hand 8A of the indexer robot IR.

The processing pattern C is a process step of locating the substrate W to be processed in the transfer point PS. The processing pattern D is a process step of taking the substrate W to be processed out from the transfer point PS. During the performance of the processing pattern C, one substrate W occupies a shelf PS1 of the transfer point PS. During the performance of the processing pattern D, one substrate W occupies the shelf PS1 of the transfer point PS.

The processing pattern E is a process step of taking the substrate W to be processed out from the transfer point PS through a conveyance robot CR. The processing pattern F is a process step of conveying the substrate W to be processed to any one of substrate processing sections PU through the conveyance robot CR and then loading the substrate W to be processed into the substrate processing section PU to which the substrate W has been conveyed. During the performance of the processing pattern E, one substrate W occupies the hand 13A of the conveyance robot CR. During the performance of the processing pattern F, one substrate W occupies the hand 13A of the conveyance robot CR.

The processing pattern G is a process step of performing substrate processing through any of the substrate processing sections PU. During the performance of the processing pattern G, one substrate W occupies any of the substrate processing sections PU.

The processing pattern H is a process step of unloading, through the conveyance robot CR, a substrate W processed from a substrate processing section PU which has processed the substrate W. The processing pattern I is a process step of, through the conveyance robot CR, conveying the substrate W processed to the transfer point PS and then locating the substrate W processed in the transfer point PS. During the performance of the processing pattern H, one substrate W occupies a hand 13B of the conveyance robot CR. During the performance of the processing pattern I, one substrate W occupies the hand 13B of the conveyance robot CR.

The processing pattern J is a process step of locating the substrate W processed in the transfer point PS. The processing pattern K is a process step of taking the substrate W processed out from the transfer point PS. During the performance of the processing pattern J, one substrate W occupies a shelf PS2 of the transfer point PS. During the performance of the processing pattern K, one substrate W occupies the shelf PS2 of the transfer point PS.

The processing pattern L is a process step of taking the substrate W processed out from the transfer point PS through the indexer robot IR. The processing pattern M is a process step of, through the indexer robot IR, conveying the substrate W processed to the substrate storage container CA and then loading the substrate W processed into the substrate storage container CA. During the performance of the processing pattern L, one substrate W occupies a hand 8B of the indexer robot IR. During the performance of the processing pattern M, one substrate W occupies the hand 8B of the indexer robot IR.

As described above with reference to FIG. 3, one substrate W sequentially occupies a plurality of components included in the substrate processing apparatus WP. Thus, the processing patterns A to M indicate occupancy information by one substrate W. In the substrate processing apparatus WP as depicted in FIG. 2, one substrate W sequentially occupies any one of: the hands 8A and 8B of the indexer robot IR; the shelves PS1 and PS2 of the transfer point PS; the hands 13A and 13B of the conveyance robot CR; and the substrate processing sections PU. A plurality of components included in the substrate processing apparatus WP are exemplified by the hands 8A and 8B of the indexer robot IR, the shelves PS1 and PS2 of the transfer point PS, the hands 13A and 13B of the conveyance robot CR, and four substrate processing sections PU (first to fourth substrate processing sections PU1 to PU4).

Processing time PT will then be described. The processing time PT is an amount of time taken when a corresponding process step is performed through the substrate processing apparatus WP. Specifically, each processing time PT is an amount of time taken when a corresponding component included in the substrate processing apparatus WP performs its own process step. In other words, each processing time PT is an amount of time taken when one substrate W occupies the corresponding component included in the substrate processing apparatus WP.

As depicted in FIG. 3, the processing times PT corresponding to the substrate processing apparatus WP (see FIG. 2) include processing times X1 to X13. The processing time X1 is an amount of time that the processing pattern A takes. The processing time X2 is an amount of time that the processing pattern B takes. The processing time X3 is an amount of time that the processing pattern C takes. The processing time X4 is an amount of time that the processing pattern D takes. The processing time X5 is an amount of time that the processing pattern E takes. The processing time X6 is an amount of time that the processing pattern F takes. The processing time X7 is an amount of time that the processing pattern G takes. The processing time X8 is an amount of time that the processing pattern H takes. The processing time X9 is an amount of time that the processing pattern I takes. The processing time X10 is an amount of time that the processing pattern J takes. The processing time X11 is an amount of time that the processing pattern K takes. The processing time X12 is an amount of time that the processing pattern L takes. The processing time X13 is an amount of time that the processing pattern M takes.

The processing times X1 to X13 are associated with the processing patterns A to M, respectively and stored in the storage 102 (see FIGS. 1A and 1B). Of the processing times X1 to X13, each of the processing times X1 to X6 is an amount of time taken when a substrate W is conveyed, and each of the processing times X8 to X13 is an amount of time taken when a substrate W is conveyed. The processing time X7 is an amount of time taken by substrate processing. Each amount of the processing times X1 to X6 is smaller than an amount of the processing time X7. Each amount of the processing times X8 to X13 is smaller than the amount of the processing time X7.

Planning factor BL will then be described. As depicted in FIG. 3, the processing procedure PD is divided into the planning factors BL. Each of the planning factors BL includes at least one of the processing patterns included in the processing procedure PD. In the example of FIG. 3, the processing patterns A to M are divided into four planning factors BL (first to fourth planning factors BL1 to BL4). Respective planning factors BL indicate the components continuously occupied by a substrate W. The planning factors BL are given in advance to the processing procedure PD. In other words, a plurality of planning factors BL is given in advance to one substrate W.

The first planning factor BL1 includes the processing patterns A to C. That is, the first planning factor BL1 indicates a plan to convey, through the indexer robot IR, a substrates W to be processed from the substrate storage container CA to the shelf PS1 of the transfer point PS. The first planning factor BL1 also indicates that one substrate W continuously occupies the hand 8A of the indexer robot IR and the shelf PS1 of the transfer point PS.

The second planning factor BL2 includes the processing patterns D to G. That is, the second planning factor BL2 indicates a plan to convey, through the conveyance robot CR, a substrate W to be processed from the shelf PS1 of the transfer point PS to any one of the substrate processing sections PU and then process the substrate W to be processed through the substrate processing section PU to which the substrate W has been conveyed. The second planning factor BL2 also indicates that one substrate W continuously occupies the shelf PS1 of the transfer point PS, the hand 13A of the conveyance robot CR, and one of the substrate processing sections PU.

The third planning factor BL3 includes the processing patterns H to J. That is, the third planning factor BL3 indicates a plan to convey, through the conveyance robot CR, a substrate W processed to the shelf PS2 of the transfer point PS from a substrate processing section PU which has processed the substrate W. In other words, the third planning factor BL3 indicates that one substrate W continuously occupies the hand 13B of the conveyance robot CR and the shelf PS2 of the transfer point PS.

The fourth planning factor BL4 includes the processing patterns K to M. That is, the fourth planning factor BL4 indicates a plan to convey the substrate W processed from the shelf PS2 of the transfer point PS to the substrate storage container CA. The fourth planning factor BL4 also indicates that one substrate W continuously occupies the shelf PS2 of the transfer point PS and the hand 8B of the indexer robot IR.

An arithmetic processing unit 105 (see FIGS. 1A and 1B) arranges the planning factors BL in the timetable TB according to the order derived from the processing procedure PD. Specifically, the arithmetic processing unit 105 arranges the planning factors BL along with the processing patterns A to M divided into the planning factors BL in the timetable TB according to the order derived from the processing procedure PD. Arranging the planning factors BL along with the processing patterns A to M divided into the planning factors BL in the timetable TB makes it possible to prohibit physically impossible actions in the substrate processing apparatus WP.

A processing procedure PD and planning factors BL will then be described with reference to FIG. 4. FIG. 4 illustrates details of a second planning factor BL2 (see FIG. 3). As described with reference to FIG. 2, one substrate W is processed by any one of first to fourth substrate processing sections PU1 to PU4. The second planning factor BL2 therefore includes four second planning factors BL2-1, BL2-2, BL2-3, and BL2-4 as depicted in FIG. 4. Seven planning factors BL are given in advance to the processing procedure PD (one substrate W). An arithmetic processing unit 105 (see FIGS. 1A and 1B) arranges a second planning factor BL2 in a timetable TB so that one of the four second planning factors BL2-1, BL2-2, BL2-3, and BL2-4 is arranged.

Specifically, the second planning factor BL2-1 indicates that a first substrate processing section PU1 processes a substrate W. In other words, the second planning factor BL2-1 indicates that one substrate W occupies the first substrate processing section PU1. Similarly, the second planning factors BL2-2 to BL2-4 indicate that the second to fourth substrate processing sections PU2 to PU4 process their respective substrates W.

Constraint conditions will then be described. Table 1 below depicts an example of the constraint conditions corresponding to a substrate processing apparatus WP (see FIG. 2). The constraint conditions are conditions for arranging planning factors BL in a timetable TB. The constraint conditions depend on the apparatus configuration of the substrate processing apparatus WP. For example, the constraint conditions include conditions that prohibit physically impossible actions in the substrate processing apparatus WP.

TABLE 1

| Constraint | |
|---|---|
| conditions | Contents of constraints |
| Constraint 1 | Advance process step according to processing procedure. |
| Constraint 2 | Hand 8A of indexer robot IR conveys substrates W to be |
| | processed one by one. |
| Constraint 3 | Hand 8B of indexer robot IR conveys substrates W |
| | processed one by one. |
| Constraint 4 | Shelf PS1 of transfer point PS supports one substrate W to |
| | be processed. |
| Constraint 5 | Shelf PS2 of transfer point PS supports one substrate W |
| | processed. |
| Constraint 6 | Hand 13A of conveyance robot CR conveys substrates W to |
| | be processed one by one. |
| Constraint 7 | Hand 13B of conveyance robot CR conveys substrates W |
| | processed one by one. |
| Constraint 8 | Substrate processing section PU processes substrates W one |
| | by one. |
| Constraint 9 | Arrange processing patterns in timetable for each planning |
| | factor BL. |

An arithmetic processing unit 105 (see FIGS. 1A and 1B) arranges the planning factors BL (planning factors A to M) in the timetable TB with reference to the constraint conditions. The constraint conditions are stored in storage 102. The constraint conditions may be included in a creation program PL1 or may be entered through the input device 101 operated by operators.

As described above with reference to FIGS. 1A, 1B, 2 to 4, and Table 1, the arithmetic processing unit 105 refers to information on the processing procedure PD, information on the processing times PT, information on the planning factors BL, and constraint conditions when arranging the planning factors BL in the timetable TB. The arithmetic processing unit 105 further refers to information on the number of substrates W when arranging the planning factors BL in the timetable TB. Hereinafter, the information on the number of substrates W may be referred to as “number information”. The number information may be included in the creation program PL1 or may be entered through the input device 101 operated by operators.

The arithmetic processing unit 105 refers to the number information and arranges in the timetable TB the planning factors BL whose number corresponds to the number of substrates W. For example, it is assumed that the number information indicates 25 on the condition that four planning factors BL are arranged in the timetable TB for each substrate W. In this case, the arithmetic processing unit 105 arranges 100 planning factors BL in each step of reinforcement learning, thereby creating a time schedule.

A timetable TB will be described with reference to FIGS. 1A, 1B, and 2 to 5. FIG. 5 depicts an example of a timetable TB corresponding to a substrate processing apparatus WP as depicted in FIG. 2. As depicted in FIG. 5, a plurality of planning factors BL is arranged in the timetable TB. Each of the planning factors BL is arranged in the timetable TB and exclusively occupies at least one of a plurality of components included in the substrate processing apparatus WP. The planning factors BL are arranged in the timetable TB, whereby a time schedule for each component of the substrate processing apparatus WP is defined. In other words, the planning factors BL are arranged in the timetable TB, whereby the scheduled occupancy time of each component of the substrate processing apparatus WP is defined.

Specifically, the horizontal axis of the timetable TB is labeled with time. The timetable TB in FIG. 5 depicts times t0, t1, t2, t3, t4, t5, t6, t7, t8, 19, t10, t11, t12, and t13. Processing patterns are arranged in the timetable TB along the time axis of the timetable TB with each processing pattern associated with a corresponding component of the substrate processing apparatus WP. First to fourth planning factors BL1 to BL4 (processing patterns A to M) (see FIGS. 3 and 4) are arranged in the timetable TB of FIG. 5 based on Constraints 1 to 9 in Table 1. The timetable TB is, for example a Gantt chart. Note that the processing patterns A to M arranged in the timetable TB may be numerical information or image information.

The second planning factor BL2 includes the processing pattern G (substrate processing) as depicted in FIGS. 3 to 5. The amount of time that the second planning factor BL2 takes is therefore larger than an amount of time that each of the other planning factors BL (first, third, and fourth planning factors BL1, BL3, and BL4) takes. The second planning factor BL2 is an example of a planning factor indicating a plan to load a substrate W to be processed into any one of substrate processing sections PU through a conveyance robot CR (conveyance section) and then process the substrate W to be processed through the substrate processing section PU to which the substrate W has been loaded. The third planning factor BL3 is an example of a planning factor indicating a plan to unload, through the conveyance robot CR (conveyance section), a substrate W processed through any of the substrate processing sections PU from the substrate processing section PU which has processed the substrate W.

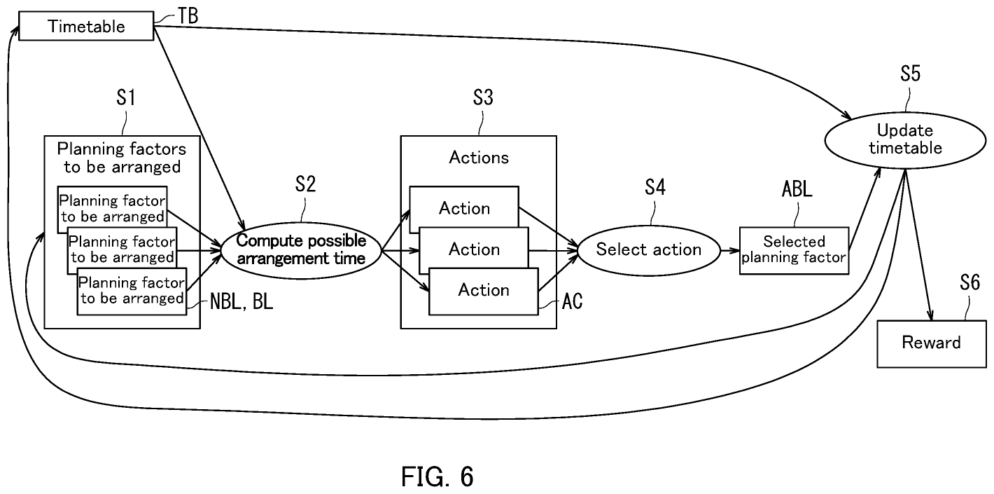

A process of creating a time schedule will then be described with reference to FIGS. 1A, 1B, and 2 to 6. FIG. 6 depicts an example of a process flow of creating a time schedule. Specifically, FIG. 6 depicts a process of arranging a plurality of planning factors BL in a timetable TB. Hereinafter, the process of arranging the plurality of planning factors BL in the timetable TB may be referred to as a “time schedule creating 20 process”.

As depicted in FIG. 6, an arithmetic processing unit 105 refers to a current state of the timetable TB and the plurality of planning factors BL and then acquires planning factors BL that have not been arranged in the timetable TB (Step S1). Hereinafter, the planning factors BL that have not been arranged may be referred to as a “planning factors NBL”.

For example, at the start of the time schedule creating process, all planning factors BL are planning factors NBL. For example, it is assumed that number information is 25 on the condition that four planning factors BL are arranged in the timetable TB for each substrate W. In this case, at the start of time schedule creating process, the arithmetic processing unit 105 acquires 100 planning factors NBL. As the time schedule creating process progresses, the number of planning factors NBL decreases. The time schedule creating process continues until the number of planning factors NBL becomes zero.

The arithmetic processing unit 105 acquires one or more planning factors NBL. The arithmetic processing unit 105 then refers to a current state of the timetable TB, the one or more planning factors NBL, constraint conditions (constraints 1 to 9), and a processing procedure PD and then acquires one or more planning factors BL to be arranged next of the planning factors NBL. Here, the planning factor BL to be arranged next is a planning factor BL to be arranged next in the timetable TB. Hereinafter, the planning factor BL to be arranged next may be referred to as a “planning factor ABL”.

The arithmetic processing unit 105 acquires one or more planning factors ABL. The arithmetic processing unit 105 then refers to a current state of the timetable TB, the one or more planning factors ABL, the constraint conditions (constraints 1 to 9), and the processing procedure PD and then calculates a possible arrangement time of each of the one or more planning factors ABL (Step S2). The possible arrangement time corresponds to the time indicated by the timetable TB. Specifically, the possible arrangement time indicates a time, included in the timetable TB, at which a process step included in the planning factor ABL can be started.

The arithmetic processing unit 105 calculates the one or more possible arrangement times and then generates an action AC for each of the one or more planning factors ABL (Step S3). The action AC indicates a behavior of arranging the planning factor ABL at the possible arrangement time in the timetable TB.

The arithmetic processing unit 105 generates one or more actions AC and then selects one of the one or more actions AC (Step S4). The arithmetic processing unit 105 then arranges one planning factor BL (planning factor ABL) in the timetable TB based on the action AC selected (Step S5). As a result, the timetable TB is updated. In other words, the timetable TB shifts to the following state.

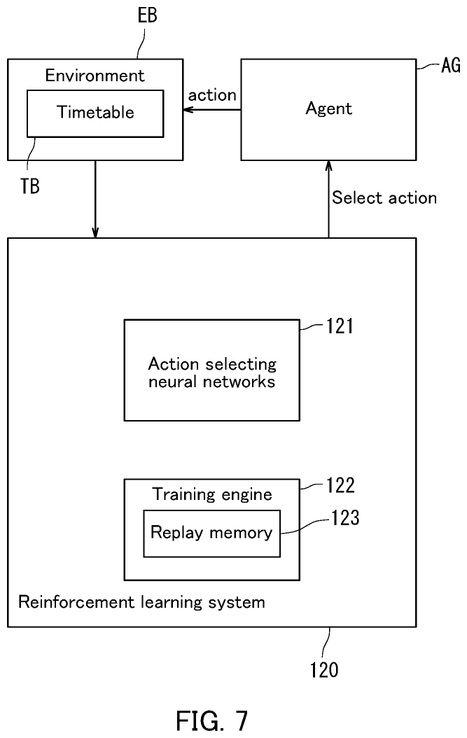

Here, a first example of a process step of selecting an action AC will be described. For example, an arithmetic processing unit 105 randomly selects one of actions AC in the initial stage of reinforcement learning. When the number of times a step (trial) of the reinforcement learning is repeated is equal to or larger than a second threshold, the arithmetic processing unit 105 predicts and selects, of the actions AC, an action AC that provides the highest reward. Specifically, a creation program PL1 includes action selecting neural networks 121 (see FIG. 7). The action selecting neural networks 121 include artificial neural networks that build a predictor. The predictor calculates an evaluation value for each action AC. The evaluation value indicates an expected value of the reward. The evaluation value is, for example a Q value. The arithmetic processing unit 105 (action selecting neural networks 121) selects the action AC with the largest evaluation value (largest expected value of reward).

Note that the arithmetic processing unit 105 may randomly select one of the actions AC based on a first condition determined in advance, after the number of times a step (trial) of reinforcement learning is repeated is equal to or larger than the second threshold. For example, the first condition may indicate a cycle for randomly selecting one of the actions AC. In this case, the arithmetic processing unit 105 periodically selects one of the actions AC at random.

In the first condition, the timing of randomly selecting one of the actions AC may be indicated by the step iteration numbers (trial numbers). The step iteration numbers define the timing of randomly selecting one of the actions AC and may hereinafter be referred to as a “randomly selecting step numbers”. The randomly selecting step numbers may indicate each value of a plurality of values. In this case, the arithmetic processing unit 105 randomly selects one of the actions AC each time the step iteration numbers (trial numbers) of the reinforcement learning reaches a value included in the randomly selecting step numbers. Note that one step (one trial) indicates a process step from starting the process of creating the time schedule to acquiring a reward by arranging all the planning factors BL in the timetable TB.

A second example of a process step of selecting an action AC will then be described. For example, an arithmetic processing unit 105 acquires a random number and determines whether a value of the random number acquired is larger than or equal to a third threshold. When the value of the random number is larger than or equal to the third threshold, the arithmetic processing unit 105 predicts and selects, of actions AC, an action AC that provides the highest reward. When the value of the random number acquired is less than the third threshold, the arithmetic processing unit 105 randomly selects one of the actions AC. The arithmetic processing unit 105 decreases the third threshold as step iteration numbers (trial numbers) increase.

When a timetable TB is updated, the arithmetic processing unit 105 performs process steps of Steps S1 to S5 again. The arithmetic processing unit 105 repeats the process steps of Steps S1 to S5 until the number of planning factors NBL becomes zero. As a result, the process of creating a time schedule ends.

When the process of creating the time schedule ends, the arithmetic processing unit 105 determines a reward based on the final state of the timetable TB and a reward function (Step S6). As already described, the reward function is defined so that a higher reward is given as an amount of time taken according to the time schedule is smaller.

A reinforcement learning system 120 built by an arithmetic processing unit 105 executing a creation program PL1 will be described with reference to FIG. 7. FIG. 7 is a block diagram depicting the reinforcement learning system 120.

As depicted in FIG. 7, the reinforcement learning system 120 selects an action of an agent AG. The action of the agent AG causes interaction between the agent AG and environment EB. Specifically, the action of the agent AG includes an action AC as described with reference to FIG. 6. The environment EB includes a timetable TB as described with reference to FIG. 5. The reinforcement learning system 120 selects actions AC as described with reference to FIG. 6. The agent AG arranges planning factors BL in the timetable TB based on the actions AC selected.

The reinforcement learning system 120 includes action selecting neural networks 121 and a training engine 122. The training engine 122 includes replay memory 123. The replay memory 123 is included in a storage area of storage 102 as described with reference to FIGS. 1A and 1B.

As already described, the action selecting neural networks 121 calculate an evaluation value (Q value) for each action AC and selects an action AC with the largest evaluation value. The training engine 122 trains the action selecting neural networks 121 and adjusts a plurality of parameters (weighting coefficients) included in the action selecting neural networks 121.

Specifically, the training engine 122 stores empirical data in the replay memory 123. The empirical data represents the results obtained by the agent AG interacting with the environment EB. The empirical data is learning data (training data) for supervised learning. The training engine 122 makes the action selecting neural networks 121 learn from the empirical data, thereby training the action selecting neural networks 121. As a result, the plurality of parameters (weighting coefficients) included in the action selecting neural networks 121 is adjusted, thereby improving the prediction accuracy of the action selecting neural networks 121.

Specifically, the training engine 122 (arithmetic processing unit 105) generates empirical data and stores the empirical data in the replay memory 123 every time a planning factor BL is arranged in the timetable TB. The empirical data includes the current state of the timetable TB, current one or more planning factors NBL (planning factors BL to be arranged), current one or more possible arrangement times, an action AC selected (planning factor ABL selected), and the next state of the timetable TB. The empirical data when the creation of a time schedule is completed further includes the value of a reward.

The training engine 122 (arithmetic processing unit 105) trains the action selecting neural networks 121 based on a second condition determined in advance. For example, the second condition may indicate a cycle for training the action selecting neural networks 121. In this case, the training engine 122 (arithmetic processing unit 105) periodically trains the action selecting neural networks 121.

Alternatively, the second condition may represent step iteration numbers as the timing for training the action selecting neural networks 121. Hereinafter, the step iteration numbers that define the timing for training the action selecting neural networks 121 may be referred to as “training step numbers”. The training step numbers indicate a plurality of values. In this case, the training engine 122 (arithmetic processing unit 105) causes the action selecting neural networks 121 to learn from empirical data every time the step iteration numbers (trial numbers) of reinforcement learning reaches a value included in the training step numbers.

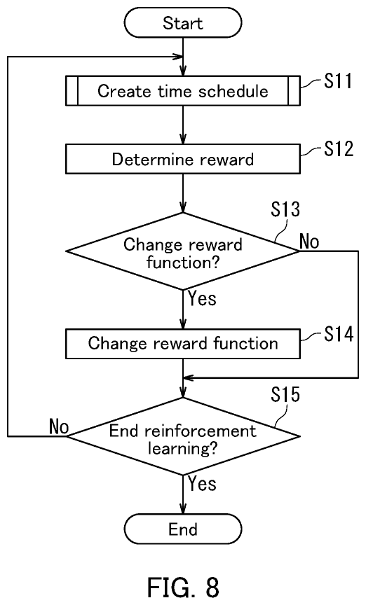

A schedule creation program generating method as an example according to the present embodiment will be described with reference to FIGS. 1A, 1B, and 2 to 16. FIG. 8 is a flow chart illustrating the schedule creation program generating method according to the present embodiment. The schedule creation program generating method according to the present embodiment is performed by a schedule creation program generating apparatus 100 as described with reference to FIGS. 1A, 1B, and 2 to 7. Specifically, the schedule creation program generating method according to the present embodiment is performed by an arithmetic processing unit 105 as described with reference to FIGS. 1A, 1B, and 2 to 7. FIG. 8 is therefore a flow illustrating a process performed by the arithmetic processing unit 105.

As depicted in FIG. 8, the schedule creation program generating method according to the present embodiment includes Steps S11 to S15. For example, the process depicted in FIG. 8 may be started in response to an instruction on starting reinforcement learning issued through an input device 101 operated by operators with a creation program PL1 installed in the schedule creation program generating apparatus 100.

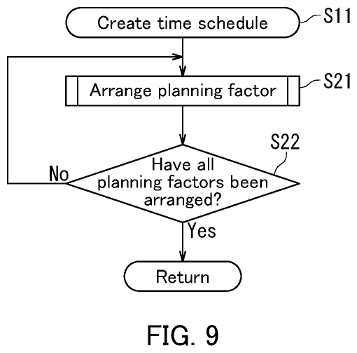

The process depicted in FIG. 8 is started. The arithmetic processing unit 105 then creates a time schedule (Step S11). A process of creating the time schedule will be described later with reference to FIG. 9. Step S11 is an example of “arranging”.

After the time schedule is created, the arithmetic processing unit 105 determines the value of a reward based on the final state of the timetable TB and a reward function (Step S12). Note that the final state of the timetable TB is the state of the timetable TB in which all planning factors BL are arranged. The time schedule corresponds to the final state of the timetable TB. Step S12 is an example of “reward determining”.

After the value of the reward is determined, the arithmetic processing unit 105 determines whether or not to change the reward function (Step S13). Specifically, the arithmetic processing unit 105 determines whether or not to change the reward function based on a third condition determined in advance. For example, the third condition may indicate a cycle for changing the reward function. In this case, the arithmetic processing unit 105 periodically changes the reward function.

Alternatively, the third condition may represent step iteration numbers as the timing of changing the reward function. The step iteration numbers define the timing of changing the reward function and may hereinafter be referred to as “change step numbers”. The change step numbers indicate at least one value. In this case, the arithmetic processing unit 105 determines to change the reward function every time the step iteration numbers (trial numbers) of reinforcement learning reaches a value included in the change step numbers.

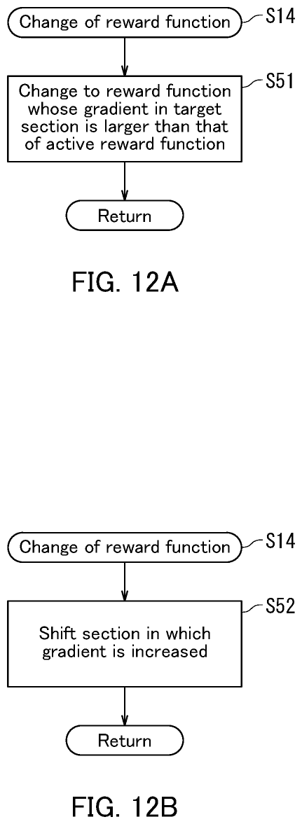

A decision is made to change the reward function (Yes in Step S13). In this case, the arithmetic processing unit 105 performs a change process step, thereby changing the reward function (Step S14). The change process step will be described later with reference to FIGS. 12A, 12B, and 13 to 16. Step S14 is an example of “changing”.

The reward function is changed and then the arithmetic processing unit 105 determines whether to end the reinforcement learning (Step S15). On the other hand, when a determination is made not to change the reward function (No in Step S13), the arithmetic processing unit 105 determines whether to end the reinforcement learning (Step S15).

The arithmetic processing unit 105 makes a determination not to end the reinforcement learning (No in Step S15). In this case, the process in FIG. 8 returns to the process step of Step S11. Conversely, the arithmetic processing unit 105 makes a determination to end the reinforcement learning (Yes in Step S15). In this case, the process in FIG. 8 ends.

For example, a first threshold may be set as a condition for ending the reinforcement learning as described with reference to FIGS. 1A and 1B. In this case, the arithmetic processing unit 105 determines to end the reinforcement learning when the number of times (trial numbers) a step(s) of reinforcement learning is (are) repeated becomes equal to or larger than the first threshold.

As described with reference to FIGS. 6 and 7, the arithmetic processing unit 105 adjusts parameters (weighting coefficients) of action selecting neural networks 121 in the process of repeating a time schedule creation process. Thus, repetition of the step (trial numbers) of reinforcement learning increases the value of the reward. In the present embodiment, one step (one trial) of reinforcement learning includes Steps S11 to S15 in FIG. 8. Note that of Steps S11 to S15, Steps S11 and S12 are an example of “experiencing”.

A time schedule creating process (step S11) as depicted in FIG. 8 will then be described with reference to FIG. 9. FIG. 9 is a flow chart illustrating the time schedule creating process.

As depicted in FIG. 9, the time schedule creating process includes Steps S21 and S22. An arithmetic processing unit 105 starts the time schedule creating process. The arithmetic processing unit 105 then arranges one of a plurality of planning factors BL in a timetable TB to change the state of the timetable TB (Step S21).

One of the plurality of planning factors BL is arranged in the timetable TB and then the arithmetic processing unit 105 determines whether all the planning factors BL have been arranged in the timetable TB (Step S22).

The arithmetic processing unit 105 determines that all the planning factors BL have been arranged in the timetable TB (Yes in Step S22). In this case, the time schedule creating process ends and the arithmetic processing unit 105 determines the value of a reward (Step S12 in FIG. 8).

The arithmetic processing unit 105 determines that a part of the planning factors BL has not been arranged in the timetable TB (No in Step S22). In this case, the process returns to Step S21 and a next planning factor BL is selected and arranged in the timetable TB. In this way, the arithmetic processing unit 105 sequentially arranges the plurality of planning factors BL in the timetable TB and sequentially changes the state of the timetable TB.

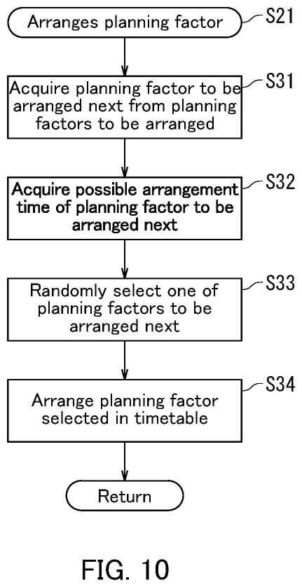

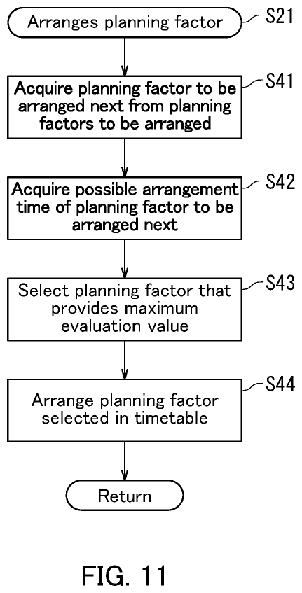

A process of arranging planning factors BL in a timetable TB (see Step S21 in FIG. 9) will be described with reference to FIGS. 10 and 11. As described with reference to FIGS. 6 and 7, an arithmetic processing unit 105 randomly selects one of actions AC and then arranges, in the timetable TB, one of planning factors BL to be arranged next (planning factors ABL). Alternatively, the arithmetic processing unit 105 predicts and selects, of the actions AC, an action AC that provides the highest reward and then arranges, in the timetable TB, one of the planning factors BL to be arranged next (planning factors ABL).

FIG. 10 is a flow chart illustrating a process of randomly selecting one of actions AC and then arranging a planning factor BL in a timetable TB. As depicted in FIG. 10, one of the actions AC is randomly selected. In this case, a process of arranging a planning factor BL in the timetable TB (see Step S21 in FIG. 9) includes Steps S31 to S34.

The arithmetic processing unit 105 starts the process of arranging a planning factor BL in the timetable TB. The arithmetic processing unit 105 then acquires, from one or more planning factors BL (planning factors NBL) to be arranged, one or more planning factors BL (planning factors ABL) to be arranged next in the timetable TB (Step S31).

The arithmetic processing unit 105 acquires the one or more planning factors BL (planning factors ABL) to be arranged next and then acquires a possible arrangement time of each of the one or more planning factors ABL (Step S32). The arithmetic processing unit 105 acquires the one or more possible arrangement times and then randomly selects one of the one or more planning factors ABL (Step S33). Specifically, the arithmetic processing unit 105 generates an action AC for each planning factor ABL and then randomly selects one of the one or more actions AC.

The arithmetic processing unit 105 arranges, in the timetable TB, the planning factor ABL randomly selected (Step S34). As a result, the process in FIG. 10 ends. Specifically, the arithmetic processing unit 105 arranges the planning factors BL (planning factors ABL) in the timetable TB based on the actions AC randomly selected.

Note that when one of the planning factors ABL is randomly selected, a second planning factor BL2 may be selected. In this case, one of second planning factors BL2-1 to BL2-4 is randomly selected. In other words, one of first to fourth substrate processing sections PU1 to PU4 is selected. A second planning factor BL2 corresponding to the substrate processing section PU selected is then arranged in the timetable TB.

FIG. 11 is a flow chart illustrating a process of predicting an action AC that provides a maximum reward and arranging planning factors BL in a timetable TB. As depicted in FIG. 11, when the action AC that provides the maximum reward is predicted, the process of arranging the planning factors BL in the timetable TB (see Step S21 in FIG. 9) includes Steps S41 to S44.

Steps S41, S42, and S44 in FIG. 11 are the same as Steps S31, S32, and S34 in FIG. 10 and description thereof will be omitted.

As depicted in FIG. 11, after acquiring one or more possible arrangement times, an arithmetic processing unit 105 selects a planning factor BL (planning factor ABL) that provides a maximum evaluation value (an expected value of a reward) (Step S43). Specifically, the arithmetic processing unit 105 generates an action AC for each of the one or more planning factors ABL. The arithmetic processing unit 105 then selects, from one or more actions AC, an action AC that provides a maximum evaluation value using an action selecting neural networks 121 (see FIG. 7). The arithmetic processing unit 105 arranges the planning factor BL (the planning factor ABL) in the timetable TB based on the action AC selected.

Note that a second planning factor BL2 may be selected when one of one or more planning factors ABL is selected. In this case, one of second plan factors BL2-1 to BL2-4 is selected. In other words, one of first to fourth substrate processing sections PU1 to PU4 is selected. A second planning factor BL2 corresponding to the substrate processing section PU selected is then arranged in a timetable TB.

A change process (Step S14) as depicted in FIG. 8 will be described with reference to FIG. 12A. FIG. 12A is a flow chart illustrating a first change process included in the change process. As depicted in FIG. 12A, an arithmetic processing unit 105 determines to change a reward function and then changes an active reward function to a reward function whose gradient in a target section TS is larger than a gradient in the target section TS of the active reward function (Step S51). The process in FIG. 12A then ends.

In the present embodiment, the change process (Step S14) may further include a second change process depicted in FIG. 12B. FIG. 12B is a flow chart illustrating the second change process included in the change process. As depicted in FIG. 12B, the arithmetic processing unit 105 determines to change the reward function and then further shifts the section (the target section TS) in which the gradient is increased by the process (first change process) in FIG. 12A (Step S52). The process in FIG. 12B then ends.

The arithmetic processing unit 105 may perform the first change process in FIG. 12A every time a determination is made to change the reward function. Therefore, the gradient in the target section TS gradually increases. Alternatively, the first change process may be performed only once. For example, the arithmetic processing unit 105 may perform the first change process only when a first determination is made to change the reward function.

After the first change process is performed at least once, the arithmetic processing unit 105 performs the second change process in FIG. 12B. The arithmetic processing unit 105 may alternately perform the first change process and the second change process. Alternatively, the arithmetic processing unit 105 may firstly perform the first change process and then simultaneously perform the first and second change processes every time a determination is made to change the reward function. The arithmetic processing unit 105 may also firstly perform the first change process and then perform only the second change process every time a determination is made to change the reward function. Note that the second change process may be omitted.

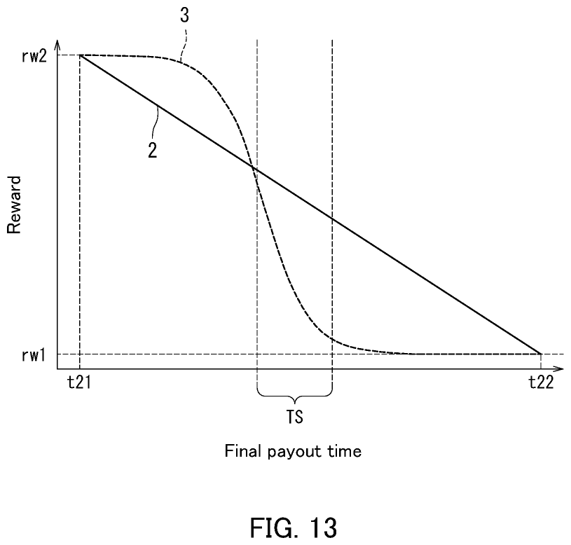

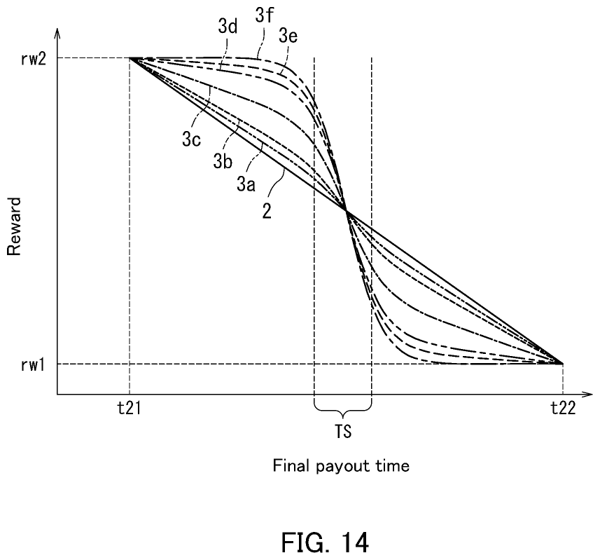

A first change process will then be described with reference to FIGS. 13 and 14. FIG. 13 depicts an example of the first change process. Specifically, FIG. 13 illustrates a reward function 2 at the beginning and a reward function 3 that has undergone the first change process. In FIG. 13, the horizontal axis is labeled with final payout time and the vertical axis is labeled with reward. Here, the final payout time corresponds to the time when, in a substrate processing apparatus WP, a last substrate W returns to a substrate storage container CA. That is, the final payout time and an amount of time taken according to a time schedule are associated with each other.

As depicted in FIG. 13, the reward functions 2 and 3 define the relationship between the amount of time taken according to a time schedule and the value of a corresponding reward such that the smaller the amount of time taken according to the time schedule, the larger the value of the corresponding reward. The reward functions 2 and 3 also define a reward with a minimum value rw1, a reward with a maximum value rw2, an amount of time (final payout time t22) taken according to a time schedule corresponding to the reward with the minimum value rw1, and an amount of time (final payout time t21) taken according to a time schedule corresponding to the reward with the maximum value rw2.

As depicted in FIG. 13, the reward function 3 includes a function whose gradient in the target section TS is larger than that of the reward function 2. The reward function 2 includes, for example a linear function. The reward function 3 includes, for example a nonlinear function. In the example of FIG. 13, the reward function 2 is a linear function whose reward has a value that monotonically decreases from the maximum value rw2 at the final payout time t21 to the minimum value rw1 at the final payout time t22. The reward function 3 includes a function that describes a logistics curve whose gradient in the target section TS is larger than that of the linear function.

The target section TS is a partial section of the time range from the final payout time t21 to the final payout time t22. The target section TS may be set according to, for example, of the time range from the final payout time t21 to the final payout time t22, a partial section in which the reward has a saturated value.

Specifically, reinforcement learning is performed based on a linear function like the reward function 2 that defines the relationship between the amount of time taken according to a time schedule and the value of a corresponding reward. In this case, evaluation values in trials have small differences before an amount of time (value of reward) taken according to the time schedule reaches a target value. As a result, a value of a reward (learning curve (not illustrated)) may have a saturation value before the amount of time (value of reward) taken according to the time schedule reaches the target value. This is considered to be caused by the fact that the substrate processing apparatus WP includes a component with a significantly different processing time PT.

Specifically, a processing time PT (processing time X7) of a substrate processing section PU is significantly different from a processing time PT of a conveyance section (indexer robot IR and conveyance robot CR). Therefore, as depicted in FIG. 5, an amount of time that second planning factors BL2 take is larger than an amount of time that the other planning factors BL (first, third, and fourth planning factors BL1, BL3, and BL4) take. Therefore, a linear function defining the relationship between an amount of time taken according to a time schedule and a value of a corresponding reward causes a mixture of selection of actions with small differences in evaluation values and selection of actions with large differences in evaluation values. As learning progresses and the reward has a value close to a target value, the actions with small differences in evaluation values are repeatedly selected and the reward is to have a saturation value before acquiring the target value.

In contrast, the present embodiment increases the gradient of the reward function in the target section TS. The differences in evaluation values among trials can therefore be expanded in the target section TS. As a result, even if trials are repeated in the target section TS, action selecting neural networks 121 can have larger (more dynamic) parameters (weighting factors). Thus, a target section TS is set to a partial section in which a reward has a saturation value when a linear function is employed as a reward function, such that differences in evaluation values among trials are expanded. It is therefore possible to prevent the reward from having the saturation value before an amount of time taken according to a time schedule (value of reward) reaches a target value.

In the present embodiment, a reward function is changed during performance of reinforcement learning. This approach enables generation of a schedule creation program PL2 that can bring an amount of time taken according to a time schedule closer to a target value.

FIG. 14 is a diagram depicting a first change process as another example. Specifically, FIG. 14 illustrates a reward function 2 at the beginning and reward functions 3a, 3b, 3c, 3d, 3e, and 3f that have undergone the first change process more than once. In FIG. 14, the horizontal axis is labeled with final payout time and the vertical axis is labeled with reward.

As depicted in FIG. 14, each of the reward functions 3a to 3f includes a function whose gradient in a target section TS is larger than that of the reward function 2. Specifically, the reward functions 3a to 3f have their respective gradients that are larger in this order in the target section TS. In this way, an arithmetic processing unit 105 may perform the first change process more than once, thereby gradually increasing the gradient in the target section TS. Specifically, the arithmetic processing unit 105 may change an active reward function to a reward function whose gradient in the target section TS is larger than that of the active reward function, for each performance of the first change process.

The reward functions 3a to 3f include, for example nonlinear functions. In the example of FIG. 14, each of the reward functions 3a to 3f includes a function that describes a logistics curve whose gradient in the target section TS is larger than that of a linear function. More specifically, the reward functions 3a to 3f are represented by a function that describes a logistics curve whose gradient is a variable. In this case, the arithmetic processing unit 105 changes a value of a constant included in the function that describes the logistics curve whose gradient is a variable each time the arithmetic processing unit 105 performs the first change process, thereby gradually increasing the gradient in the target section TS.

In the present embodiment, the gradient in the target section TS is gradually increased as depicted in FIG. 14. Differences in evaluation values among trials are therefore gradually expanded. Thus, parameters of action selecting neural networks 121 can be changed gradually. The learning efficiency of reinforcement learning can therefore be improved.

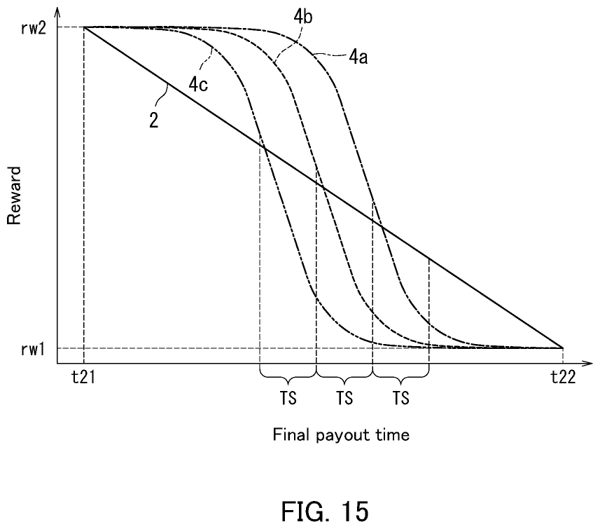

A second change process will then be described with reference to FIG. 15. FIG. 15 is a diagram illustrating an example of the second change process. Specifically, FIG. 15 illustrates a reward function 2 at the beginning and reward functions 4a, 4b, and 4c that have undergone the second change process more than once. In FIG. 15, the horizontal axis is labeled with final payout time and the vertical axis is labeled with reward.

As depicted in FIG. 15, the reward functions 4a to 4c define a relationship between an amount of time taken according to a time schedule and a value of a corresponding reward such that the smaller an amount of time taken according to a time schedule, the larger the value of a corresponding reward. The reward functions 4a to 4c also define a reward with a minimum value rw1, a reward with a maximum value rw2, an amount of time (final payout time t22) taken according to a time schedule corresponding to the reward with the minimum value rw1, and an amount of time (final payout time t21) taken according to a time schedule corresponding to the reward with the maximum value rw2.

As depicted in FIG. 15, the reward functions 4a to 4c include their respective functions whose gradients in their respective target sections TS are larger than that of the reward function 2. The partial sections (target sections TS), in which their respective gradients are larger, of the reward functions 4a to 4c differ from each other. Specifically, respective positions of the target sections TS become closer to the final payout time t21 in the order of the reward functions 4a to 4c. In this way, an arithmetic processing unit 105 may perform the second change process more than once, thereby shifting a target section TS from the final payout time t22 side to the final payout time t21 side.

For example, each of the reward functions 4a to 4c is a nonlinear function. In the example of FIG. 15, each of the reward functions 4a to 4c includes a function that describes a logistics curve whose gradient in the target section TS is larger than that of a linear function. More specifically, the reward functions 4a to 4c are represented by a function of X-axis variable logistics curve. In this case, the arithmetic processing unit 105 changes a value of a constant included in the function of X-axis variable logistics curve every time the arithmetic processing unit 105 performs the second change process, thereby shifting a target section TS from the final payout time t22 side to the final payout time t21 side.

The approach by the present embodiment makes it possible to generate a schedule creation program PL2 that can bring an amount of time taken according to a time schedule closer to a target value without previously determining a partial section in which a reward acquired from a linear function as a reward function has a saturation value.

In the example of FIG. 15, the target section TS is shifted with the gradient in the target section TS kept constant. The gradient in the target section TS may however be gradually increased while shifting the target section TS as described with reference to FIG. 14.

In the example depicted in FIGS. 13 to 15, each of the reward functions 3, 3a to 3f, and 4a to 4c that have undergone the change process is a nonlinear function. The reward functions that have undergone the change process are no limited to the nonlinear function as long as their respective gradients in the target sections TS are larger than that of the reward function 2. For example, a reward function that has undergone a change process may include a linear function whose gradient in a target section TS is larger than that of the reward function 2.

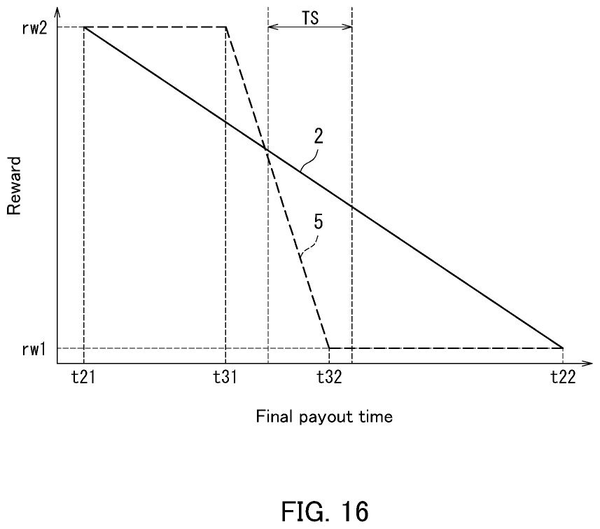

FIG. 16 is a diagram depicting a change process as another example. Specifically, FIG. 16 illustrates a reward function 2 at the beginning and a reward function 5 that has undergone a change process. In FIG. 16, the horizontal axis is labeled with final payout time and the vertical axis is labeled with reward.

As depicted in FIG. 16, the reward function 5 defines a relationship between an amount of time taken according to a time schedule and a value of a corresponding reward such that in a time range from a final payout time t31 to a final payout time t32, the smaller the amount of time taken according to the time schedule, the larger the value of the corresponding reward. The reward function 5 also defines a reward with a minimum value rw1, a reward with a maximum value rw2, an amount of time (range from final payout time t32 to final payout time t22) taken according to a time schedule corresponding to the reward with the minimum value rw1, and an amount of time (range from final payout time t21 to final payout time t31) taken according to a time schedule corresponding to the reward with the maximum value rw2.

As depicted in FIG. 16, the reward function 5 includes a function whose gradient in a target section TS is larger than that of the reward function 2. At least part of the target section TS is included in the time range from the final payout time t31 to the final payout time t32. Specifically, the reward function 5 includes a linear function whose gradient is larger than that of the reward function 2 (linear function). The linear function included in the reward function 5 linearly changes a value of a reward at a final payout time in the time range from the final payout time t31 to the final payout time t32.

The reward function 5 depicted in FIG. 16 makes the gradient in the target section TS larger than that of the reward function 2. It is therefore possible to generate a schedule creation program PL2 that can bring the amount of time taken along to the time schedule closer to a target value like the reward functions 3, 3a to 3f, and 4a to 4c described with reference to FIGS. 13 to 15.

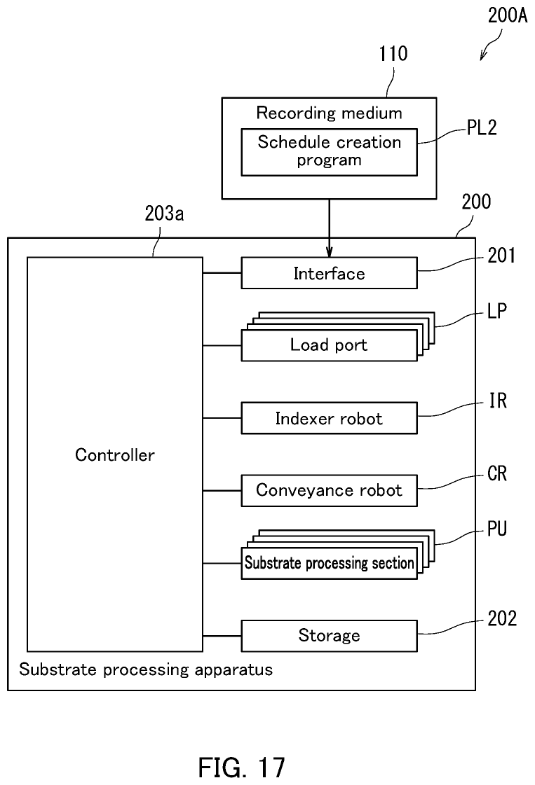

A substrate processing apparatus 200 as an example according to the present embodiment will then be described with reference to FIG. 17. FIG. 17 is a diagram illustrating a substrate processing system 200A including the substrate processing apparatus 200 according to the present embodiment.

As depicted in FIG. 17, the substrate processing system 200A includes a recording medium 110 and the substrate processing apparatus 200. The substrate processing apparatus 200 includes an interface 201, a plurality of load ports LP, an indexer robot IR, a conveyance robot CR, a plurality of substrate processing sections PU, storage 202, and controller 203a.

The interface 103 exchanges information, data, or signals with the recording medium 110. Specifically, the recording medium 110 stores a schedule creation program PL2 as described with reference to FIGS. 1A, 1B, and 2 to 16. The interface 201 reads the schedule creation program PL2 from the recording medium 110 and enters the schedule creation program PL2 into the controller 203a.

The configuration of the interface 201 is the same as that of the interface 103 described with reference to FIGS. 1A and 1B and therefore a detailed description thereof will be omitted. In addition, respective configurations of the load ports LP, the indexer robot IR, the conveyance robot CR, and the substrate processing sections PU are the same as those of the load ports LP, the indexer robot IR, the conveyance robot CR, and the substrate processing sections PU described with reference to FIG. 2 and therefore the description thereof will be omitted.

The storage 202 stores various information for controlling the operation of the substrate processing apparatus 200. For example, the storage 202 stores data and a computer program. The data includes various recipe data. Examples of the recipe data include a process recipe. The process recipe is data that defines a procedure for substrate processing. The storage 202 also stores the schedule creation program PL2 read from the recording medium 110. The storage 202 further stores a processing procedure PD, processing times PT, planning factors BL, and constraint conditions.

The storage 202 includes main memory. Examples of the main memory include semiconductor memory. The storage 202 may further include auxiliary storage. The auxiliary storage includes, for example at least one of devices that include semiconductor memory and a hard disk drive. The storage 202 may also include removable media.

The controller 203a includes, for example a processor. Examples of the processor in the controller 203a include a CPU and an MPU. Examples of the controller 203a may further include a general-purpose computing device and a dedicated computing device. The controller 203a controls the operation of each section of the substrate processing apparatus 200 based on various information stored in the storage 202. For example, the controller 203a controls the interface 201, the load ports LP, the indexer robot IR, the conveyance robot CR, the substrate processing sections PU, and the storage 202.

The controller 203a also executes the schedule creation program PL2 when processing a plurality of substrates W. The controller 203a then creates a time schedule in which the plurality of substrates W sequentially occupies a plurality of components included in the substrate processing apparatus 200. Here, the plurality of components includes the indexer robot IR, a transfer point PS, the conveyance robot CR, and the substrate processing sections PU. The controller 203a then controls the load ports LP, the indexer robot IR, the conveyance robot CR, and the substrate processing sections PU according to the time schedule created.

Specifically, the schedule creation program PL2 includes action selecting neural networks 121 whose parameters (weighting coefficients) have been adjusted as described with reference to FIGS. 1A, 1B, and 2 to 16. The controller 203a creates the time schedule according to Steps S1 to S5 as described with reference to FIG. 6 based on the schedule creation program PL2, the processing procedure PD, the processing times PT, the planning factors BL, and the constraint conditions.

In the present embodiment, an amount of time taken according to the time schedule can be brought closer to a target value through the schedule creation program PL2 as described with reference to FIGS. 1A, 1B, and 2 to 16. This approach enables the substrate processing apparatus 200 to create a time schedule according to which a process of processing a predetermined number of substrates W is to be completed in a shorter period of time.

The first embodiment has been described above with reference to FIGS. 1A, 1B, and 2 to 17. In the present embodiment, there is no need to develop the entire flow of processing performed by a processor. Specifically, developers only need to develop a processing procedure PD, processing times PT, planning factors BL, and constraint conditions. The burden on the developers can therefore be reduced.

The approach by the present embodiment enables generating a schedule creation program PL2 that can bring an amount of time taken according to a time schedule closer to a target value.

In the present embodiment, a linear function can be used as a reward function at the beginning for reinforcement learning. The learning efficiency of reinforcement learning can therefore be improved.

Specifically, at the beginning of reinforcement learning, a time schedule with a relatively late final payout time is created. Differences in evaluation values among trials at the initial stage of reinforcement learning therefore become smaller when using, as the initial reward function of the reinforcement learning, the reward function 3, the reward functions 3a to 3f, the reward functions 4a to 4c, or the reward function 5 described with reference to FIGS. 13 to 16. The reward is therefore unlikely to have a large value. As a result, the reinforcement learning decreases in learning efficiency. In contrast, in the first embodiment, a linear function is employed as an initial reward function of reinforcement learning. As a result, differences in evaluation values among trials can be larger than those of the reward function 3, the reward functions 3a to 3f, the reward functions 4a to 4c, or the reward function 5 even if a time schedule in which a final payout time is relatively late is created. The reinforcement learning can therefore be improved in learning efficiency.

### Second Embodiment

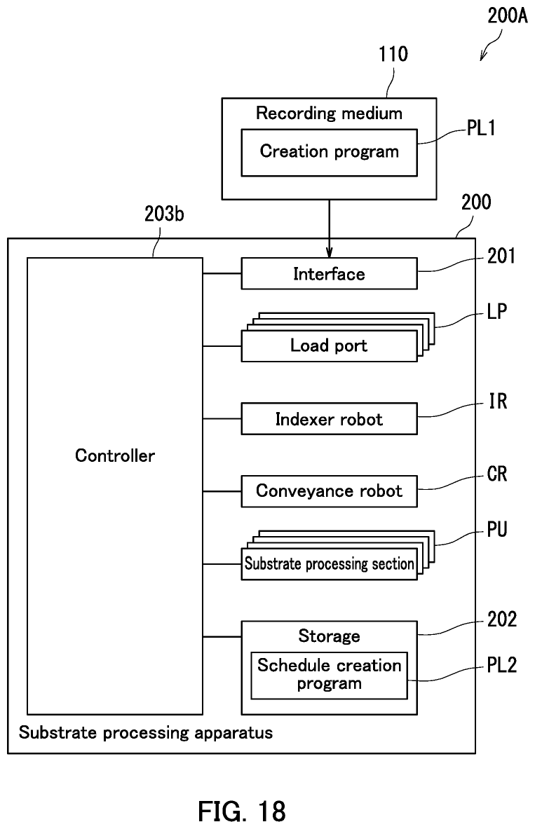

A second embodiment will then be described with reference to FIG. 18. However, matters that are different from the first embodiment will be described and description of matters that are the same as the first embodiment will be omitted. In the second embodiment, a substrate processing apparatus 200 generates a schedule creation program PL2 unlike the first embodiment.

FIG. 18 is a diagram illustrating a substrate processing system 200A including the substrate processing apparatus 200 according to the present embodiment. As depicted in FIG. 18, the substrate processing system 200A includes a recording medium 110 and the substrate processing apparatus 200. The substrate processing apparatus 200 includes an interface 201, a plurality of load ports LP, an indexer robot IR, a conveyance robot CR, a plurality of substrate processing sections PU, storage 202, and controller 203b.

The recording medium 110 stores a creation program PL1 as described with reference to FIGS. 1A, 1B, and 2 to 16. The interface 201 of the substrate processing apparatus 200 reads the creation program PL1 from the recording medium 110 and enters the creation program PL1 into the controller 203b.

The storage 202 stores the creation program PL1 read from the recording medium 110. The storage 202 also stores a processing procedure PD, processing times PT, planning factors BL, and constraint conditions as described with reference to FIG. 17.

The controller 203b includes, for example a processor. Examples of the processor in the controller 203b include a CPU, an MPU, a GPU, an NPU, and a quantum computer. Examples of the controller 203b may further include a general-purpose computing device and a dedicated computing device. The controller 203b controls the operation of each section of the substrate processing apparatus 200 based on various information stored in the storage 202. For example, the controller 203b controls the interface 201, the load ports LP, the indexer robot IR, the conveyance robot CR, the substrate processing sections PU, and the storage 202.

The controller 203b executes the creation program PL1 to generate the schedule creation program PL2 like the arithmetic processing unit 105 described with reference to FIGS. 1A, 1B, and 2 to 16. The schedule creation program PL2 is stored in the storage 202. The controller 203b executes the schedule creation program PL2 to create a time schedule like the controller 203a described with reference to FIG. 17 when processing a plurality of substrates W. The controller 203b then controls the load ports LP, the indexer robot IR, the conveyance robot CR, and the substrate processing sections PU according to the time schedule created.

The second embodiment has been described above with reference to FIG. 18. In the second embodiment, the burden on developers can be reduced like the first embodiment. In the second embodiment, an amount of time taken according to the time schedule can be brought closer to a target value through the schedule creation program PL2 like the first embodiment. This approach enables the substrate processing apparatus 200 to create a time schedule which a process of processing a predetermined number of substrates W is to be completed in a shorter period of time according to.

### Third Embodiment

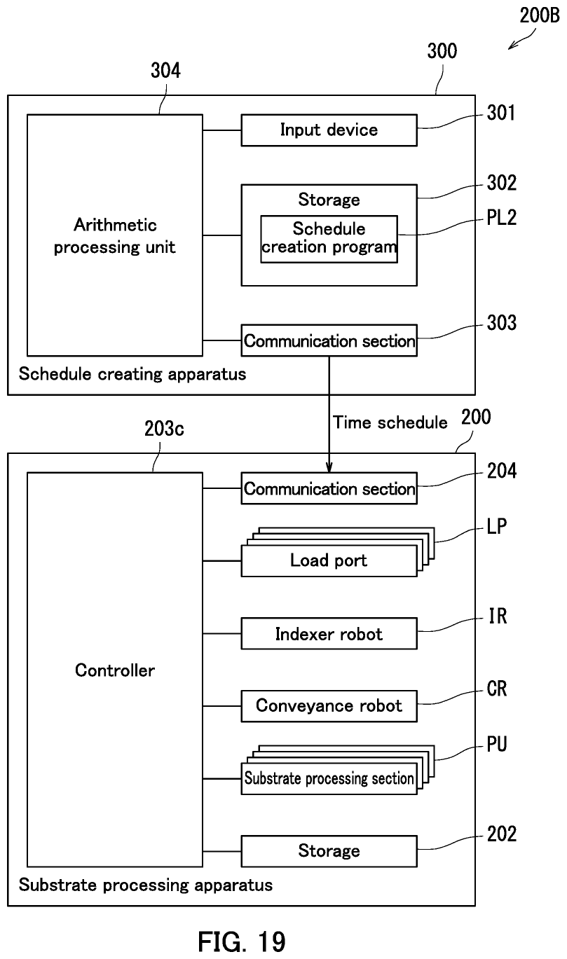

A third embodiment will then be described with reference to FIG. 19. However, matters that are different from the first and second embodiments will be described and description of matters that are the same as the first and second embodiments will be omitted. In the third embodiment, a substrate processing system 200B includes a schedule creating apparatus 300 unlike the first and second embodiments.

FIG. 19 is a diagram illustrating the substrate processing system 200B according to the present embodiment. As depicted in FIG. 19, the substrate processing system 200B includes the schedule creating apparatus 300 and a substrate processing apparatus 200.

The schedule creating apparatus 300 creates a time schedule based on a schedule creation program PL2. Specifically, the schedule creating apparatus 300 includes an input device 301, storage 302, a communication section 303, and an arithmetic processing unit 304. The schedule creating apparatus 300 is, for example a server.

The input device 301 includes a user interface device that allows operators to operate. The input device 301 allows operators to enter a signal into the arithmetic processing unit 304. Here, the signal is issued through the input device 301 operated by the operators. The configuration of the input device 301 is the same as that of the input device 101 described with reference to FIGS. 1A and 1B and therefore description thereof will be omitted. For example, operators can operate the input device 301 to issue an instruction to start creating a time schedule.

The storage 302 includes main memory. The main memory includes, for examples semiconductor memory. The storage 302 may further include auxiliary storage. The auxiliary storage includes, for example at least one of devices that include semiconductor memory and a hard disk drive. The storage 302 may also include removable media. The storage 302 stores various computer programs and various data. Specifically, the storage 302 stores the schedule creation program PL2. The schedule creation program PL2 is generated based on the creation program PL1 as described with reference to FIGS. 1A, 1B, and 2 to 16.

The arithmetic processing unit 304 includes, for example a processor. Examples of the processor in the arithmetic processing unit 304 include a CPU and an MPU. Examples of the arithmetic processing unit 304 may further include a general-purpose computing device and a dedicated computing device. The arithmetic processing unit 304 executes the schedule creation program PL2 stored in the storage 302 like the controller 203a described with reference to FIG. 17. The arithmetic processing unit 304 then creates a time schedule in which a plurality of substrates W sequentially occupies a plurality of components included in the substrate processing apparatus 200. Here, the plurality of components includes an indexer robot IR, a transfer point PS, a conveyance robot CR, and substrate processing sections PU.

The communication section 303 is connected to a network and communicates with the substrate processing apparatus 200. Examples of the network include the Internet, a local area network (LAN), a public switched telephone network, and near-field communication. The communication section 303 includes telecommunications equipment. The communication section 303 is, for example a network interface controller. Under the control of the arithmetic processing unit 304, the communication section 303 transmits a time schedule created by the arithmetic processing unit 304 to the substrate processing apparatus 200. The communication section 303 is an example of a “transmitter”.

The substrate processing apparatus 200 includes a plurality of load ports LP, the indexer robot IR, the conveyance robot CR, the plurality of substrate processing sections PU, storage 202, a controller 203c, and a communication section 204.

The communication section 204 is connected to a network and communicates with the communication section 303 of the schedule creating apparatus 300. The communication section 204 includes telecommunications equipment. The communication section 204 is, for example a network interface controller. The communication section 204 receives a time schedule transmitted from the communication section 303 of the schedule creating apparatus 300. The communication section 204 is an example of a “receiver”.

The controller 203c includes, for example a processor. Examples of the processor in the controller 203c include a CPU and an MPU. Examples of the controller 203c may further include a general-purpose computing device and a dedicated computing device. The controller 203c controls the operation of each section of the substrate processing apparatus 200 based on various information stored in the storage 202. For example, the controller 203c controls the load ports LP, the indexer robot IR, the conveyance robot CR, the substrate processing sections PU, the storage 202, and the communication section 204.

Specifically, the controller 203c instructs the schedule creating apparatus 300 to create a time schedule when processing a plurality of substrates W. The communication section 204 then receives the time schedule from the schedule creating apparatus 300. The controller 203c controls the load ports LP, the indexer robot IR, the conveyance robot CR, and the substrate processing sections PU based on the time schedule received by the communication section 204.

Specifically, the controller 203c causes the communication section 204 to transmit a command to create a time schedule to the schedule creating apparatus 300. The communication section 204 then receives the time schedule from the schedule creating apparatus 300. When issuing an instruction on creating a time schedule, the controller 203c may cause the communication section 204 to transmit, to the schedule creating apparatus 300, information on a processing procedure PD, information on processing times PT, information on planning factors BL, and constraint conditions.

The third embodiment has been described above with reference to FIG. 19. In the third embodiment, the burden on developers can be reduced like the first and second embodiments. The approach by the third embodiment enables creation of a time schedule which a process of processing a predetermined number of substrates W is to be completed in a shorter period of time according to.

### Fourth Embodiment

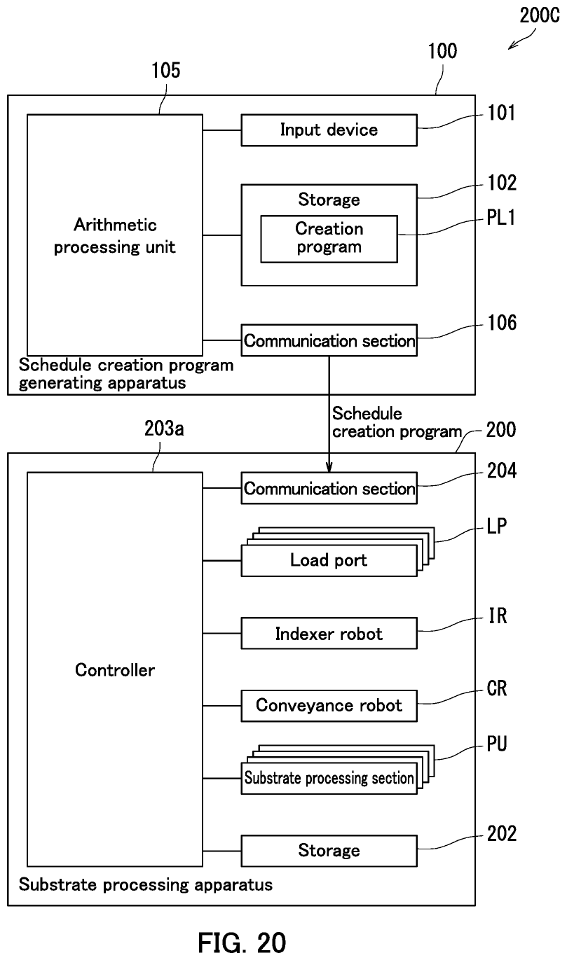

A fourth embodiment will then be described with reference to FIG. 20. However, matters that are different from the first to third embodiments will be described and description of matters that are the same as the first to third embodiments will be omitted. In the fourth embodiment, a substrate processing system 200C includes a schedule creation program generating apparatus 100 unlike the first to third embodiments.

FIG. 20 is a diagram illustrating the substrate processing system 200C according to the present embodiment. As depicted in FIG. 20, the substrate processing system 200C includes the schedule creation program generating apparatus 100 and a substrate processing apparatus 200. The schedule creation program generating apparatus 100 is, for example a server.

The schedule creation program generating apparatus 100 includes an input device 101, storage 102, an arithmetic processing unit 105, and a communication section 106. The arithmetic processing unit 105 executes a creation program PL1 stored in the storage 102 to generate a schedule creation program PL2 as described with reference to FIGS. 1A, 1B, and 2 to 16.

The communication section 106 is connected to a network and communicates with the substrate processing apparatus 200. Under the control of the arithmetic processing unit 105, the communication section 106 transmits the schedule creation program PL2 created by the arithmetic processing unit 105 to the substrate processing apparatus 200. The communication section 106 is an example of a “transmitter”. Note that the configuration of the communication section 106 is the same as that of the communication section 303 described with reference to FIG. 19 and therefore description thereof will be omitted.

The substrate processing apparatus 200 includes a plurality of load ports LP, an indexer robot IR, a conveyance robot CR, a plurality of substrate processing sections PU, storage 202, a controller 203a, and a communication section 204.

The communication section 204 is connected to a network and communicates with the communication section 106 of the schedule creation program generating apparatus 100. The communication section 204 receives a schedule creation program PL2 transmitted from the communication section 106 of the schedule creation program generating apparatus 100. The schedule creation program PL2 received by the communication section 204 is stored in the storage 202.

When processing a plurality of substrates W, the controller 203a executes the schedule creation program PL2 to create a time schedule. The controller 203a then controls the load ports LP, the indexer robot IR, the conveyance robot CR, and the substrate processing sections PU according to the time schedule created.

The fourth embodiment has been described above with reference to FIG. 20. This approach by the fourth embodiment enables the burden on developers to be reduced like the first to third embodiments. In addition, the approach enables creating a schedule creation program PL2 though which an amount of time taken according to a time schedule is to be brought closer to a target value. The approach therefore enables the substrate processing apparatus 200 to create a time schedule which a process of processing a predetermined number of substrates W is to be completed in a shorter period of time according to.

The embodiments have been described above with reference to the drawings (FIGS. 1A, 1B, and 2 to 20). However, the subject of the present application is not limited to the above-described embodiments and can be practiced in various ways within the scope without departing from the essence of the present disclosure. Furthermore, the constituent elements disclosed in the above-described embodiments may be altered as appropriate. For example, constituent elements described in different embodiments may be combined as appropriate. Some of all the constituent elements in an embodiment may be added to constituent elements of another embodiment. Some of all the constituent elements in an embodiment may be removed from the entirety thereof disclosed in the embodiment.

The drawings mainly illustrate schematic constituent elements in order to facilitate understanding of the disclosure, and thickness, length, numbers, intervals or the like of each constituent element illustrated in the drawings may differ from actual ones thereof in order to facilitate preparation of the drawings. Furthermore, the elements of configuration described in the above embodiment are merely examples and not particular limitations. The elements of configuration may be variously altered within a scope not substantially departing from the effects of the present disclosure.

For example, the substrate processing apparatus WP and the substrate processing apparatus 200 are a single-wafer type apparatus in the embodiments described with reference to FIGS. 1A, 1B, and 2 to 20, but not limited to this. The substrate processing apparatus WP and the substrate processing apparatus 200 may be a batch type apparatus.

The substrate processing apparatus 200 is not particularly limited as long as it is an apparatus that processes substrates W. Examples of the substrate processing apparatus 200 may include chemical cleaning apparatus, brush cleaning apparatus, wet etching apparatus, dry etching apparatus, coating apparatus, development apparatus, light exposure apparatus, coater developer, baking apparatus, and film forming apparatus.

In the embodiments described with reference to FIGS. 1A, 1B, and 2 to 20, examples of a reward function that has undergone a change process include a function (reward functions 3, 3a to 3f, and 4a to 4c) that represents a curved graph and a function (reward functions 5) that represents a linear graph. However, the reward function that has undergone the change process is not particularly limited as long as the gradient in the target section TS is larger than that of the reward function 2. For example, the reward function that has undergone the change process may be a step function that represents a step-like graph.

What is claimed is:

1. A schedule creation program generating method that generates, through reinforcement learning, a schedule creation program for creating a time schedule for a plurality of components included in a substrate processing apparatus,
while a substrate of the plurality of substrates is being processed, the plurality of components being occupied by the substrate,
wherein the schedule creation program generating method comprises:
increasing a value of a reward by repeating experiencing through the reinforcement learning, the experiencing including arranging and reward determining; and
changing a reward function that defines a relationship between an amount of time taken according to the time schedule and a value of a corresponding reward, wherein:
the arranging includes sequentially changing a state of a timetable by sequentially arranging a plurality of planning factors in the timetable, the timetable defining the time schedule, the plurality of planning factors being given in advance to each of the plurality of substrates;
the reward determining includes determining the value of the corresponding reward based on the reward function and a final state of the timetable in which all the plurality of planning factors are arranged;
the time schedule corresponds to the final state of the timetable; and
the changing includes changing the reward function whose gradient in a partial section is larger than a gradient in the partial section of the reward function before the changing, the partial section being part of a time range from an amount of time taken according to a time schedule corresponding to a reward with a maximum value to an amount of time taken according to a time schedule corresponding to a reward with a minimum value.

2. The schedule creation program generating method according to claim 1, wherein the changing includes changing to a reward function whose gradient in the partial section is larger than a gradient in the partial section of a linear function that is set in all the time range.

3. The schedule creation program generating method according to claim 1, wherein
the changing is repeated more than once, and
the changing includes changing to a reward function whose gradient in the partial section is larger than a gradient in the partial section of an active reward function each time the changing is repeated.

4. The schedule creation program generating method according to claim 1, wherein the changing further includes shifting the partial section.

5. The schedule creation program generating method according to claim 1,
wherein the plurality of components include
a plurality of substrate processing sections that process the plurality of substrates, and
a conveyance section that conveys the plurality of substrates,
wherein the plurality of planning factors include
a first planning factor that is a plan to load a substrate of the plurality of substrates into a substrate processing section of the plurality of substrate processing sections through the conveyance section to process the substrate through the substrate processing section, and
a second planning factor that is a plan to unload the substrate processed by the substrate processing section from the substrate processing section through the conveyance section.

6. The schedule creation program generating method according to claim 5, wherein an amount of time taken according to the first planning factor is larger than an amount of time taken according to the second planning factor.

7. The schedule creation program generating method according to claim 5, wherein
the plurality of planning factors includes respective planning factors corresponding to the plurality of substrate processing sections, and
the arranging includes selecting a planning factor of the plurality of planning factors respectively corresponding to the plurality of substrate processing sections.

8. A schedule creation program generating apparatus that generates, through reinforcement learning, a schedule creation program for creating a time schedule for a plurality of components included in a substrate processing apparatus,
wherein the schedule creation program generating apparatus comprises:
storage that stores a creation program that defines the schedule creation program generating method according to claim 1; and
a processor that executes the creation program to generate the schedule creation program.

9. A schedule creating apparatus that creates a time schedule for a plurality of components included in a substrate processing apparatus,
wherein the schedule creating apparatus comprises:
storage that stores a schedule creation program that is created based on the schedule creation program generating method according to claim 1; and
a processor that executes the schedule creation program to create the time schedule.

10. A recording medium that is a non-transitory computer readable medium, the recording medium storing a creation program that defines the schedule creation program generating method according claim 1.

11. A recording medium that is a non-transitory computer readable medium, the recording medium storing the schedule creation program created through the schedule creation program generating method according to claim 1.

12. A substrate processing apparatus that processes a substrate, the substrate processing apparatus comprising:
a plurality of components that, while a substrate of a plurality of substrates is being processed, are occupied by the substrate,
storage that stores a creation program that defines the schedule creation program generating method according to claim 1, and
a processor that executes the creation program to generate a schedule creation program for creating the time schedule for the plurality of components, the processor executing the schedule creation program to create the time schedule.

13. A substrate processing apparatus that processes a substrate, the substrate processing apparatus comprising:
a plurality of components that, while a substrate of a plurality of substrates is being processed, are occupied by the substrate,
storage that stores a schedule creation program that is generated through the schedule creation program generating method according to claim 1, and
a processor that executes the schedule creation program to create the time schedule for the plurality of components.

14. A substrate processing system comprising:
a substrate processing apparatus that processes a substrate; and
the schedule creation program generating apparatus according to claim 8, the schedule creation program generating apparatus further including a transmitter that transmits the schedule creation program to the substrate processing apparatus,
wherein the substrate processing apparatus includes:
a plurality of components that, while a substrate of a plurality of substrates is being processed, are occupied by the substrate,
a receiver that receives the schedule creation program transmitted from the transmitter of the schedule creation program generating apparatus, and
a processor that executes the schedule creation program to create the time schedule for the plurality of components.

15. A substrate processing system comprising:
a substrate processing apparatus that processes a substrate; and
the schedule creating apparatus according to claim 9, the schedule creating apparatus further including a transmitter that transmits the time schedule to the substrate processing apparatus,
wherein the substrate processing apparatus includes:
a plurality of components that, while a substrate of a plurality of substrates is being processed, are occupied by the substrate, and
a receiver that receives the time schedule transmitted from the transmitter of the schedule creating apparatus.
